(19) United States
(12) Patent Application Publication
(10) Pub. No.: US 2008/0063557 A1
(43) Pub. Date: Mar. 13, 2008

(54) Spintronics Material and Tmr Device

(75) Inventors: Shoji Ishida, Kagoshima (JP); Sou Mizutani, Kagoshima (JP)

Correspondence Address: KRATZ, QUINTOS & HANSON, LLP, 1420 K Street, N.W., Suite 400, WASHINGTON, DC, 20005, US

(73) Assignee: Kagoshima University, Kagoshima-shi (JP)

(21) Appl. No.: 11/661,854

(22) PCT Filed: Sep. 6, 2005
(86) PCT No.: PCT/JP05/16349

§ 371 Date: Mar. 5, 2007

(30) Foreign Application Priority Data
Sep. 6, 2004 (JP) 2004-258728
Feb. 22, 2005 (JP) 2005-046088

(51) Int. Cl. C22C 30/00; G11C 11/02

(52) U.S. Cl. 420/580; 365/158

(57) ABSTRACT

A spintronics material contains X₂(Mn_{1-y}Cr_{y})Z, wherein X is at least one element selected from a group consisting of Fe, Ru, Os, Co and Rh, Z is at least one element selected from a group consisting of the group IIIB elements, the group IVB elements and the group VB elements, y is 0 or more and 1 or less. Fe₂MnZ, Co₂MnZ, Co₂CrAl and Ru₂MnZ are excluded.

### TECHNICAL FIELD

The present invention relates to spintronics materials such as half-metals and TMR devices using the spintronics materials.

### BACKGROUND ART

A focus on the electric conductivities of materials may classify the materials, for example, into electricity-conducting materials (conductors), insulators, semiconductors not conducting electricity at low temperatures but conducting electricity at high temperatures, and superconductors without resistance. The mechanisms underlying such a variety of conductive properties are frequently elucidated by examining the behavior of electrons in the nano-level world.

Electrons each have a negative charge and an up-spin or down-spin magnetic moment. In other words, every electron is an upward magnet or a downward magnet. Consequently, an atom or a material in which the number of the up-spins and the number of the down-spins are different from each other undergoes spin polarization to form a magnet. A new field referred to as “spintronics” taking advantage of such a spin polarization has recently been opened up and has been being developed. Specifically, the new field relates to the development of new elements to control spin as well as charge in contrast to the fact that conventional devices control charge to take advantage thereof. If a completely spin-polarized electric current, for example, an electric current solely due to the flow of up-spin electrons is obtained, devices having functions completely different from the functions of conventional devices will be obtained and expected to be applied in a broad range of fields.

In this connection, there has been discovered a half-metal, which enables such a complete spin polarization (an electric current with completely spin polarization flows), to attract attention as a new functional material. Typical examples of the expected applications of the half-metal include a MRAM (Magnetoresistive Random Access Memory). The MRAM is a next-generation memory that takes advantage of a TMR (Tunneling Magnetoresistive) device to magnetically record data, and is being developed throughout the world under tough competition. A configuration in which two half-metal thin films sandwich an insulator thin film therebetween provides a desirable TMR device, since the spins of the two half-metal thin films orient to be opposite to each other so as to be favorable with respect to the electrostatic energy. Half-metals are also expected to be applied to quantum computers and the like.

Recently, it has been theoretically predicted that half-metals exist in a Heusler alloy X₂YZ (L2₁ type) and a half-Heusler alloy XYZ (C1_{b} type), and accordingly, experimental verification of such half-metals has been actively tried. However, the properties of the half-metal are sensitive to the disorder in the atomic arrangement, so that it is difficult to verify whether or not a half-metal is established. Accordingly, there are very few examples where half-metals have been verified. Additionally, no sufficient reports have hitherto been published on spintronics materials high in spin polarization ratio.

[Patent Document 1] Japanese Patent Application Laid-Open No. 2003-218428

[Patent Document 2] Japanese Patent Application Laid-Open No. Hei 11-18342

### SUMMARY OF THE INVENTION

An object of the present invention is to provide a spintronics material insensitive to the disorder in the atomic arrangement and capable of attaining a high spin-polarization ratio and a TMR device using the spintronics material.

As a result of painstaking research carried out to solve the above mentioned problems, the present inventor thought out the following aspects of the present invention.

A spintronics material according to the present invention includes X₂(Mn_{1-y}Cr_{y})Z. Here, X is at least one element selected from a group consisting of Fe, Ru, Os, Co and Rh, Z is at least one element selected from a group consisting of the group IIIB elements, the group IVB elements and the group VB elements, y is 0 or more and 1 or less. Fe₂MnZ, Co₂MnZ, Co₂CrAl and Ru₂MnZ are excluded.

A TMR device according to the present invention includes two ferromagnetic layers formed of the spintronics material, and a nonmagnetic layer sandwiched between the two ferromagnetic layers.

### BRIEF DESCRIPTION OF THE DRAWINGS

FIG. 1A is a graph showing an up-spin E(k) curves in Co₂MnSi;

FIG. 1B is a graph showing a down-spin E(k) curves in Co₂MnSi;

FIG. 1C is a graph showing density-of-state curves in Co₂MnSi;

FIG. 2A is a graph showing densities of state in Ru₂CrSi;

FIG. 2B is a graph showing densities of state in (Ru_{15/16}Cr_{1/16})₂(Cr_{7/8}Ru_{1/8})Si;

FIG. 2C is a graph showing densities of state in (Ru_{13/16}Cr_{3/16})₂(Cr_{5/8}Ru_{3/8})Si;

FIG. 3A is a graph showing densities of state in (Ru_{7/8}Cr_{1/8})₂(Cr_{3/4}Ru_{1/4})Si;

FIG. 3B is a graph showing densities of state in Ru₂(Cr_{3/4}Si_{1/4})(Si_{3/4}Cr_{1/4});

FIG. 3C is a graph showing the densities of state in (Ru_{7/8}Si_{1/8})₂Cr(Si_{3/4}Ru_{1/4});

FIG. 4A is a graph showing densities of state in Ru₂CrSi in a ferromagnetic state;

FIG. 4B is a graph showing densities of state in Ru₂CrGe in a ferromagnetic state;

FIG. 4C is a graph showing densities of state in Ru₂CrSn in a ferromagnetic state;

FIG. 5A is a graph showing densities of state in Fe₂CrSi in a ferromagnetic state;

FIG. 5B is a graph showing densities of state in Fe₂CrGe in a ferromagnetic state;

FIG. 5C is a graph showing densities of state in Fe₂CrSn in a ferromagnetic state;

FIG. 6A is a graph showing densities of state in (Fe_{15/16}Cr_{1/16})₂(Cr_{7/8}Fe_{1/8})Sn;

FIG. 6B is a graph showing densities of state in Fe₂(Cr_{7/8}Sn_{1/8})₂(Sn_{7/8}Cr_{1/8});

FIG. 6C is a graph showing densities of state in (Fe_{15/16}Sn_{1/16})₂Cr(Sn_{7/8}Fe_{1/8});

FIG. 7A is a graph showing densities of state in (Fe_{15/16}Cr_{1/16})₂(Cr_{7/8}Fe_{1/8})Si;

FIG. 7B is a graph showing densities of state in Fe₂(Cr_{7/8}Si_{1/8})(Si_{7/8}Cr_{1/8});

FIG. 7C is a graph showing densities of state in (Fe_{15/16}Si_{1/16})₂Cr(Si_{7/8}Fe_{1/8});

FIG. 8A is a graph showing densities of state in Os₂CrSi in a ferromagnetic state;

FIG. 8B is a graph showing densities of state in Os₂CrGe in a ferromagnetic state;

FIG. 8C is a graph showing densities of state in Os₂CrSn in a ferromagnetic state;

FIG. 9A is a graph showing densities of state in Fe₂CrP;

FIG. 9B is a graph showing densities of state in Ru₂CrP;

FIG. 9C is a graph showing densities of state in Os₂CrP;

FIG. 10A is a graph showing relations between a lattice constant and a total energy in a ferromagnetic state and in an antiferromagnetic state in Fe₂CrSi;

FIG. 10B is a graph showing relations between a lattice constant and a total energy in a ferromagnetic state and in an antiferromagnetic state in Ru₂CrSi;

FIG. 11A is a graph showing densities of state in (Fe_{1/4}Ru_{3/4})₂CrSi;

FIG. 11B is a graph showing densities of state in (Fe_{1/2}Ru_{1/2})₂CrSi;

FIG. 11C is a graph showing densities of state in (Fe_{3/4}Ru_{1/4})₂CrSi;

FIG. 12 is a graph showing relations between a total energy differences (ΔE) of two antiferromagnetic states (af1, af2) from a ferromagnetic state (f) and an Fe concentration (x) in (FeₓRu₁₋ₓ)₂CrSi;

FIG. 13A is a graph showing densities of state in (Fe_{1/2}Ru_{1/2})₂CrSi;

FIG. 13B is a graph showing densities of state in (Fe_{1/2}Ru_{1/2})₂CrGe;

FIG. 13C is a graph showing densities of state in (Fe_{1/2}Ru_{1/2})₂CrSn;

FIG. 14 is a graph showing a relation between an x value and a lattice constant in (FeₓRu₁₋ₓ)₂CrSi;

FIG. 15A is a graph showing densities of state (D(E)) in (Fe_{1/2}Os_{1/2})₂CrSi;

FIG. 15B is a graph showing densities of state (D(E)) in (Fe_{1/2}Co_{1/2})₂CrSi;

FIG. 15C is a graph showing densities of state (D(E)) in (Ru_{1/2}Os_{1/2})₂CrSi;

FIG. 15D is a graph showing densities of state (D(E)) in (Ru_{1/2}Co_{1/2})₂CrSi;

FIG. 16A is a graph showing densities of state (D(E)) in (Fe_{1/2}Ru_{1/2})₂MnSi;

FIG. 16B is a graph showing densities of state (D(E)) in (Fe_{1/2}Co_{1/2})₂MnSi;

FIG. 16C is a graph showing densities of state (D(E)) in (CO_{1/2}Rh_{1/2})₂MnSi;

FIG. 16D is a graph showing densities of state (D(E)) in (Ru_{1/2}Rh_{1/2})₂MnSi;

FIG. 17A is a graph showing densities of state in Fe₂MnSi in a ferromagnetic state;

FIG. 17B is a graph showing densities of state in Ru₂MnSi in a ferromagnetic state;

FIG. 18A is a graph showing densities of state in Fe₂(Cr_{1/2}Mn_{1/2}) Si in a ferromagnetic state;

FIG. 18B is a graph showing densities of state in Ru₂(Cr_{1/2}Mn_{1/2}) Si in a ferromagnetic state;

FIG. 19A is a graph showing densities of state (D(E)) in Fe₂CrSi in which atoms are regularly arranged;

FIG. 19B is a graph showing densities of state (D(E)) in (Fe_{1/2}Ru_{1/2})₂CrSi in which atoms are regularly arranged;

FIG. 19C is a graph showing densities of state (D(E)) in Fe₂CrSn in which atoms are regularly arranged;

FIG. 19D is a graph showing densities of state (D(E)) in Co₂MnSi in which atoms are regularly arranged;

FIG. 20A is a graph showing densities of state (D(E)) in Fe₂CrSi in which atoms are irregularly arranged;

FIG. 20B is a graph showing densities of state (D(E)) in (Fe_{1/2}Ru_{1/2})₂CrSi in which atoms are irregularly arranged;

FIG. 20C is a graph showing densities of state (D(E)) in Fe₂CrSn in which atoms are irregularly arranged;

FIG. 20D is a graph showing densities of state (D(E)) in Co₂MnSi in which atoms are irregularly arranged;

FIG. 21 is a graph showing relations between a disorder level y of Cr or Mn and a spin polarization ratio P in five alloys;

FIG. 22A is a graph showing densities of state (D(E)) in (Fe_{3/4}Ru_{1/4})₂CrSi in which atoms are regularly arranged;

FIG. 22B is a graph showing densities of state (D(E)) in (Fe_{3/4}Ru_{1/4})₂CrSi in which atoms are irregularly arranged;

FIG. 23A is a graph showing densities of state (D(E)) of the Fe d-component in (Fe_{3/4}Ru_{1/4})₂CrSi in which atoms are regularly arranged;

FIG. 23B is a graph showing densities of state (D(E)) of a Cr d-component in (Fe_{3/4}Ru_{1/4})₂CrSi in which atoms are regularly arranged;

FIG. 23C is a graph showing densities of state (D(E)) of a Ru d-component in (Fe_{3/4}Ru_{1/4})₂CrSi in which atoms are regularly arranged;

FIG. 24A is a graph showing densities of state (D(E)) of a d-component of Fe located at normal positions in (Fe_{3/4}Ru_{1/4})₂CrSi in which atoms are irregularly arranged;

FIG. 24B is a graph showing densities of state (D(E)) of a d-component of Fe occupying atomic positions other than the normal positions in (Fe_{3/4}Ru_{1/4})₂CrSi in which atoms are irregularly arranged;

FIG. 24C is a graph showing densities of state (D(E)) of a d-component of Cr located at normal positions in (Fe_{3/4}Ru_{1/4})₂CrSi in which atoms are irregularly arranged;

FIG. 24D is a graph showing densities of state (D(E)) of a d-component of Cr occupying atomic positions other than the normal positions in (Fe_{3/4}Ru_{1/4})₂CrSi in which atoms are irregularly arranged;

FIG. 24E is a graph showing densities of state (D(E)) of a d-component of Ru located at normal positions in (Fe_{3/4}Ru_{1/4})₂CrSi in which atoms are irregularly arranged;

FIG. 25A is a graph showing relations between a lattice constant and a total energy in a ferromagnetic state and in an antiferromagnetic state in Ru₂MnSi;

FIG. 25B is a graph showing relations between a lattice constant and a total energy in a ferromagnetic state and in an antiferromagnetic state in Fe₂MnSi; and

FIG. 26 is a schematic diagram illustrating a configuration of a TMR device.

### DETAILED DESCRIPTION OF THE PREFERRED EMBODIMENTS

First, description will be made on how the presence or the absence of the half-metallic properties is theoretically predicted.

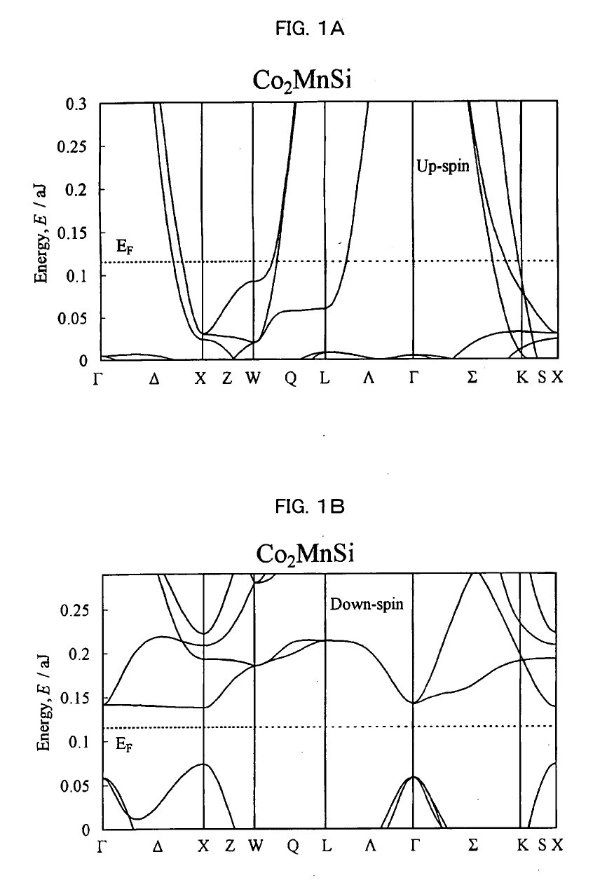

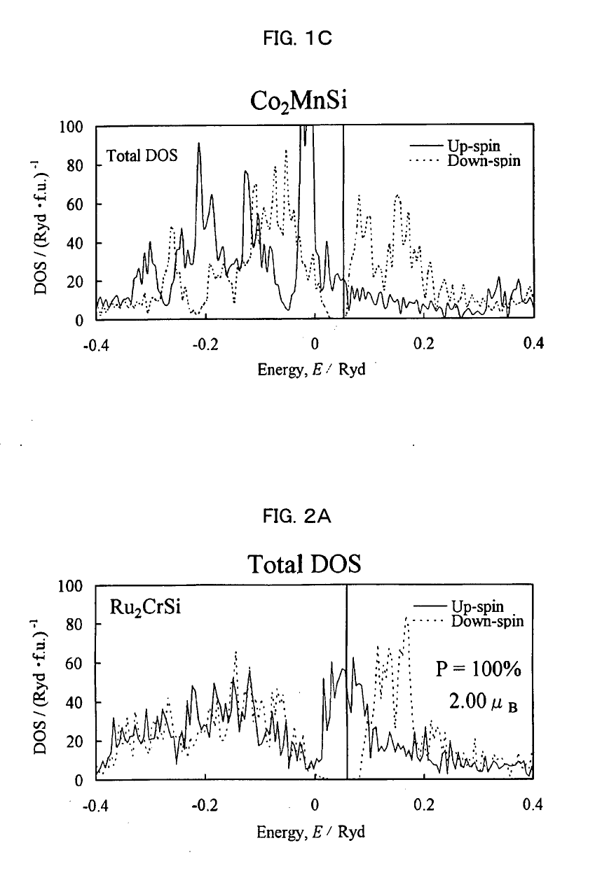

FIGS. 1A and 1B are graphs respectively showing the up-spin and down-spin E(k) curves in Co₂MnSi, and show the relations between the electronic energies (the ordinate) and the wave vectors (the abscissa: corresponding to the momentum). The horizontal lines (dotted lines) each represent the Fermi energy (E_{F}), which corresponds to the highest electronic energy. The Fermi energy E_{F} intersects the up-spin E(k) curves, but does not intersect the down-spin E(k) curves. In other words, as long as the down-spin state is concerned, the Fermi energy E_{F} falls within the energy gap. The electrons having energies in the vicinity of the Fermi energy E_{F} react with the electric field, so that the electrons in the up-spin state contribute to the electric current, but the electrons in the down-spin state do not contribute to the electric current.

FIG. 1C is a graph showing the density-of-state curves in Co₂MnSi, and shows the relation between the number of the electronic states (ordinate: D(E)) and the energy (abscissa: E). The vertical line (solid line) in FIG. 1C represents the Fermi energy E_{F}, and the states having energies equal to E_{F} or less are occupied by the electrons. Here, it is to be noted that this graph shows the results obtained by calculating the crystal potential within the framework of the LSD (Local Spin Density) approximation, and by calculating the electronic structure by means of the LMTO (Linear Muffin-Tin Orbital) method. This is also the case for the following graphs showing density-of-state curves.

As described above, in the down-spin state, the Fermi energy E_{F} of Co₂MnSi falls within the energy gap. It is to be noted that E(k) and D(E) are given in different energy units, but the Fermi energy E_{F} itself is invariant.

The spin polarization ratio P is given by
(D↑(E_{F})−D↓(E_{F}))/(D↑(E_{F})+D↓(E_{F})),
where D↑(E_{F}) represents the density of state for the up-spin state at the Fermi energy E_{F} and D↓(E_{F}) represents the density of state for the down-spin state at the Fermi energy E_{F}. The larger is the spin polarization ratio P of a material, the more suitable as a spintronics material is the material. In Co₂MnSi, D↓(E_{F})=0, and hence P=1 (spin polarization ratio of 100%). In other words, Co₂MnSi is a half-metal. However, the D↑(E_{F}) value of Co₂MnSi is smaller than those of alloys to be described below, suggesting that the spin polarization ratio is degraded by the half-metal property degradation due to the disorder in the atomic arrangement and the like.

As described above, when a material has the Fermi energy E_{F} falling within the energy gap in one of the spin states, but has no energy gap to be found at the position of the Fermi energy E_{F} in the other of the spin states with reference to the E(k) curves or the density-of-state curves (D(E)), such a material can be identified as a half-metal.

Next, description is made on an alloy represented by X₂(Mn_{1-y}Cr_{y})Z, discovered by the present inventors, insensitive to the disorder in the atomic arrangement. Here, X is at least one element selected from a group consisting of Fe, Ru, Os, Co and Rh, Z is at least one element selected from a group consisting of the group IIIB elements, the group IVB elements and the group VB elements, and y is 0 or more and 1 or less. Additionally, Fe₂MnZ, Co₂MnZ, Co₂CrAl and Ru₂MnZ are excluded. It is to be noted that no attempt has hitherto been made to obtain a half-metal or a spintronics material by disposing Mn and Cr at the Y atomic positions of a Heusler alloy.

[Ru₂CrSi]

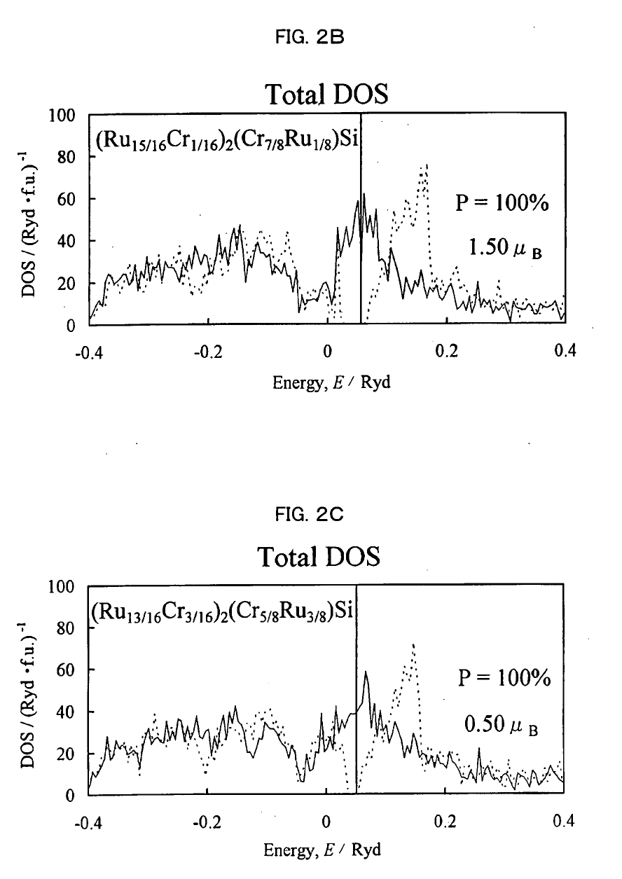

FIG. 2A is a graph showing the densities of state (D(E)) in Ru₂CrSi, FIG. 2B is a graph showing the densities of state (D(E)) in (Ru_{15/16}Cr_{1/16})₂(Cr_{7/8}Ru_{1/8})Si, and FIG. 2C is a graph showing the densities of state (D(E)) in (Ru_{13/16}Cr_{3/16})₂(Cr_{5/8}Ru_{3/8})Si. These alloys are the same in composition but are different from each other in the atomic arrangement conditions. Specifically, with Ru₂CrSi as reference, ⅛ and ⅜ of Cr are interchanged with 1/16 and 3/16 of Ru in the latter two alloys, respectively. In each of FIGS. 2A to 2C, the solid and dotted lines represent the up-spin and down-spin densities of state (D(E)), respectively.

In any of FIGS. 2A to 2C, the Fermi energy E_{F} falls within the energy gap in the down-spin state, suggesting that the half-metallicity of Ru₂CrSi is hardly degraded by the interchange between Ru and Cr.

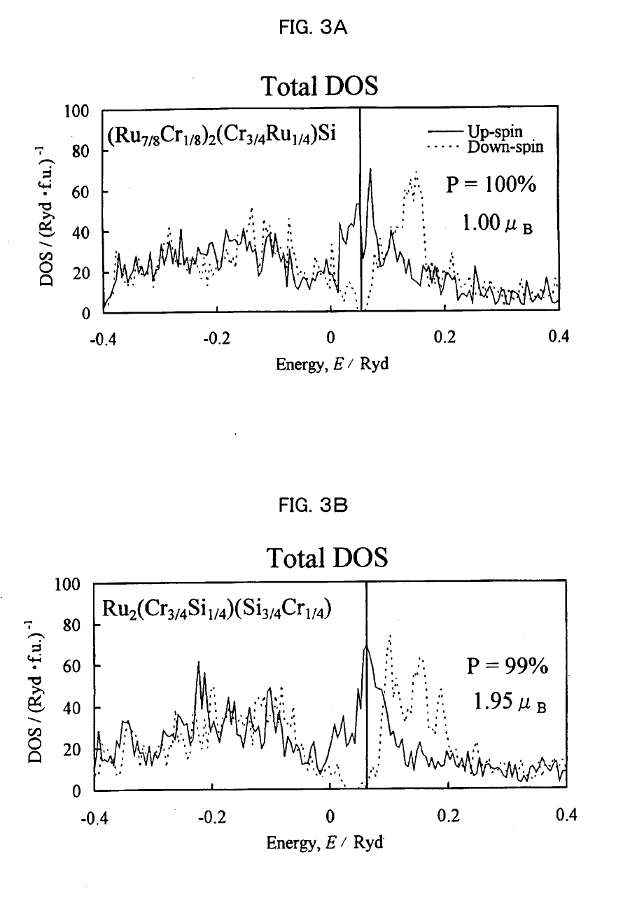

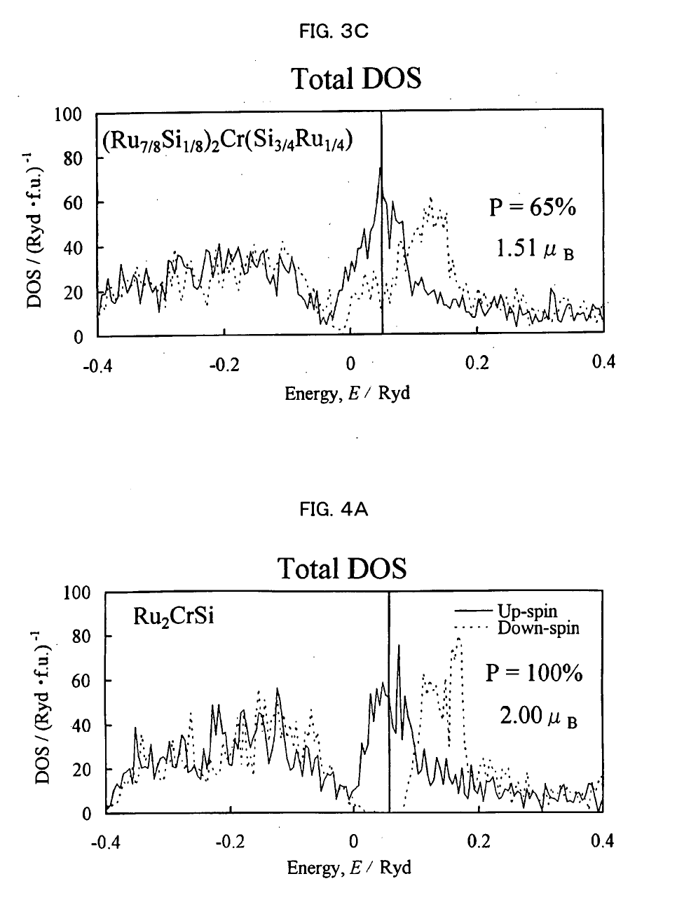

FIG. 3A is a graph showing the densities of state (D(E)) in (Ru_{7/8}Cr_{1/8})₂(Cr_{3/4}Ru_{1/4})Si, FIG. 3B is a graph showing the densities of state (D(E)) in Ru₂(Cr_{3/4}Si_{1/4})(Si_{3/4}Cr_{1/4}), and FIG. 3C is a graph showing the densities of state (D(E)) in (Ru_{7/8}Si_{1/8})₂Cr(Si_{3/4}Ru_{1/4}). These alloys are the same in composition but are different from each other in the atomic arrangement conditions. Specifically, with Ru₂CrSi as reference, ¼ of Cr is interchanged with ⅛ of Ru, ¼ of Cr is interchanged with ¼ of Si, and ⅛ of Ru is interchanged with ¼ of Si, respectively. In each of FIGS. 3A to 3C, the solid and dotted lines represent the up-spin and down-spin densities of state (D(E)), respectively.

In the interchange between Cr and Ru, similarly to the examples shown in FIGS. 2A to 2C, the spin polarization ratio P remains to be 100%, suggesting that the half-metallicity of Ru₂CrSi is hardly degraded by the interchange between Cr and Ru similarly to the above description. Additionally, in the interchange between Cr and Si, the spin polarization ratio P is 99%, thus providing no half-metal but ensuring a high spin polarization ratio. On the contrary, in the interchange between Ru and Si, the spin polarization ratio P is as low as 65%, resulting in large deviations from the half-metallic properties. However, the interchange between Ru and Si gives a high total energy to the state obtained after the interchange to make the state unstable, so that such interchange is hardly expected to occur.

[Ru₂CrZ (Z=Si, Ge, Sn)]

In view of the fact that the homologous elements (having the same number of valence electrons) in the periodic table are similar in properties to each other, description is made on the cases where any of Ge and Sn homologous to Si is used as the Z atom in a Heusler alloy (X₂YZ).

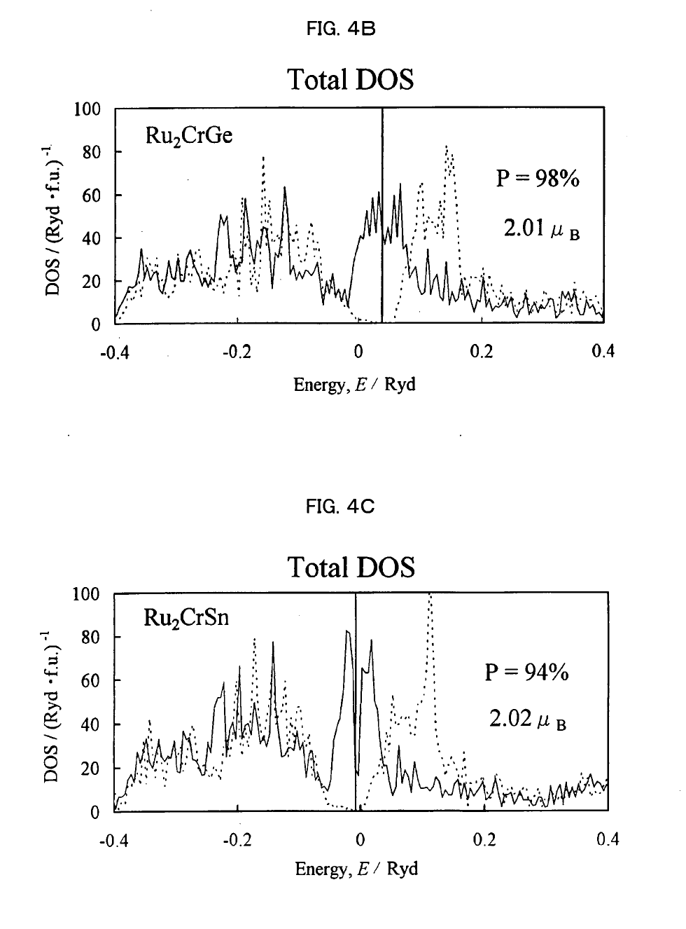

FIG. 4A is a graph showing the densities of state (D(E)) in Ru₂CrSi in a ferromagnetic state, FIG. 4B is a graph showing the densities of state (D(E)) in Ru₂CrGe in a ferromagnetic state, and FIG. 4C is a graph showing the densities of state (D(E)) in Ru₂CrSn in a ferromagnetic state. In each of FIGS. 4A to 4C, the solid and dotted lines represent the up-spin and down-spin densities of state (D(E)), respectively.

In any of these alloys, the up-spin state has a peak in the vicinity of the Fermi energy E_{F} (when Z=Sn, a steep valley is found in a large peak), and the down-spin state has a large valley in the vicinity of the Fermi energy E_{F}. These findings indicate that Ru₂CrSi is a half-metal, and Ru₂CrGe and Ru₂CrSn are materials high in spin polarization ratio. Specifically, the spin polarization ratios P of Ru₂CrGe and Ru₂CrSn are 98% and 94%, respectively. Consequently, it can be said that the difference in the Z atom does not significantly affect the gross shape of the density-of-state curves.

[Fe₂CrZ (Z=Si, Ge and Sn)]

Description is made on the cases where Fe homologous to Ru is used as the X atom in the Heusler alloy (X₂YZ).

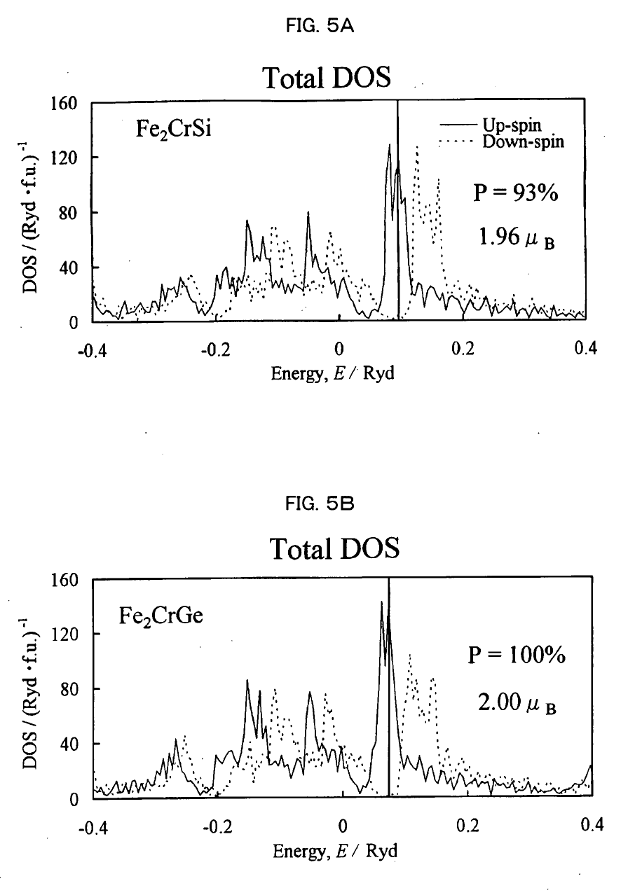

FIG. 5A is a graph showing the densities of state (D(E)) in Fe₂CrSi in a ferromagnetic state, FIG. 5B is a graph showing the densities of state (D(E)) in Fe₂CrGe in a ferromagnetic state, and FIG. 5C is a graph showing the densities of state (D(E)) in Fe₂CrSn in a ferromagnetic state. In each of FIGS. 5A to 5C, the solid and dotted lines represent the up-spin and down-spin densities of state (D(E)), respectively.

Substitution of Ru with Fe sharpens the peaks, but does not result in large differences between FIGS. 4A to 4C and FIGS. 5A to 5C, in view of the gross features. As the Z atom is altered from Si to Ge and Sn in the increasing order of atomic number, the D↑(E_{F}) value is increased with D↓(E_{F})=0 for Sn. The spin polarization ratios P of Fe₂CrSi, Fe₂CrGe and Fe₂CrSn are 93%, 100% and 100%, respectively. In other words, Fe₂CrSi is high in spin polarization ratio P and is a spintronics material close to a half-metal; Fe₂CrGe and Fe₂CrSn are half-metals.

The effects due to the disorder in the atomic arrangement caused by the interchange between the constituent atoms have been studied also on Fe₂CrSn and Fe₂CrSi.

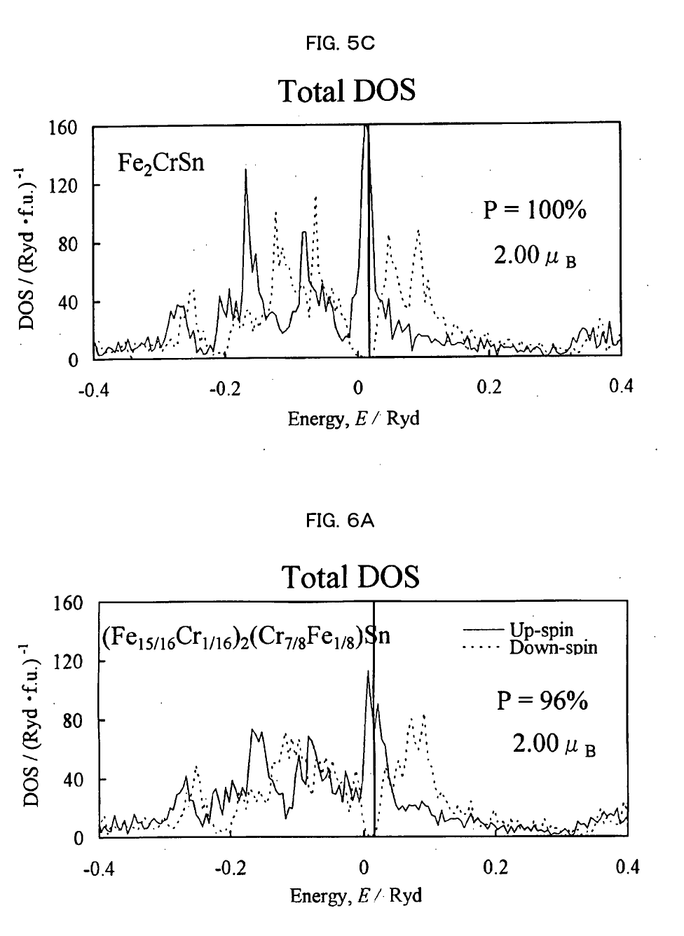

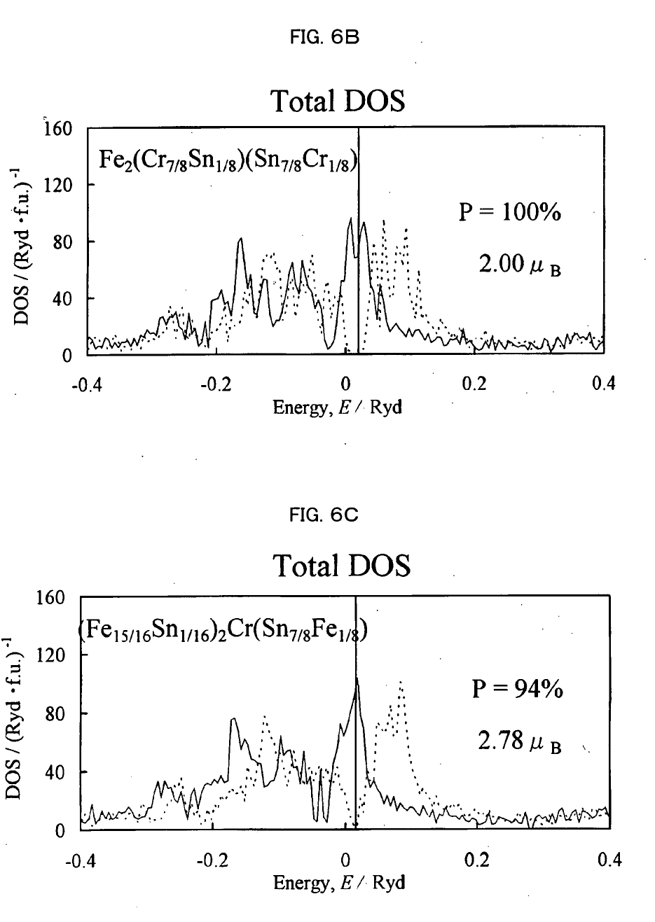

FIG. 6A is a graph showing the densities of state (D(E)) in (Fe_{15/16}Cr_{1/16})₂(Cr_{7/8}Fe_{1/8})Sn, FIG. 6B is a graph showing the densities of state (D(E)) in Fe₂(Cr_{7/8}Sn_{1/8})(Sn_{7/8}Cr_{1/8}), and FIG. 6C is a graph showing the densities of state (D(E)) in (Fe_{15/16}Sn_{1/16})₂Cr(Sn_{7/8}Fe_{1/8}). These alloys exhibit the spin polarization ratios P as high as 96%, 100% and 94%, respectively. Consequently, it can be said that the half-metallicity of Fe₂CrSn is hardly degraded by the interchange between the constituent atoms.

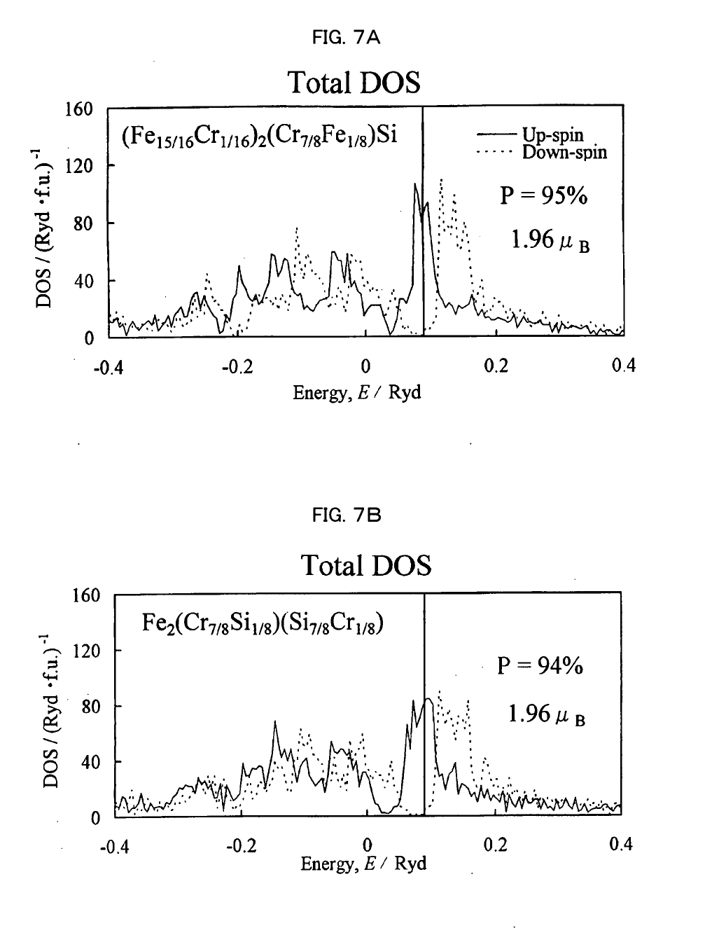

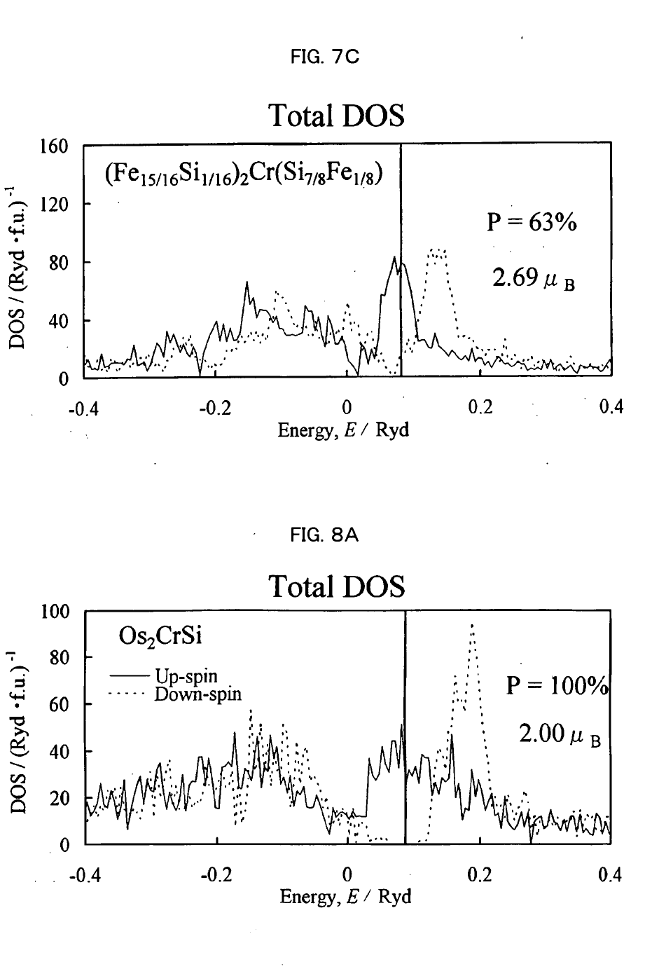

FIG. 7A is a graph showing the densities of state (D(E)) in (Fe_{15/16}Cr_{1/16})₂(Cr_{7/8}Fe_{1/8})Si, FIG. 7B is a graph showing the densities of state (D(E)) in Fe₂(Cr_{7/8}Si_{1/8})(Si_{7/8}Cr_{1/8}), and FIG. 7C is a graph showing the densities of state (D(E)) in (Fe_{15/16}Si_{1/16})₂Cr(Si_{7/8}Fe_{1/8}). The spin polarization ratios P of these alloys are 95%, 94% and 63%, respectively.

A comparison of the total energies of the alloys represented by Fe₂CrZ (Z=Si and Sn) reveals that the total energy increases in the order of the alloy with Fe—Cr interchange, the Fe₂CrZ without atomic interchange, the alloy with Cr-Z interchange and the alloy with Fe-Z interchange. The result that Fe₂CrSn becomes a half-metal has been obtained, but with Fe₂CrZ undergoing interchange between Fe and Z, the spin polarization ratio P of Fe₂CrZ is decreased. Consequently, an intermingling of the disordered portion of the atomic arrangement conceivably leads to a possibility that the spin polarization ratio P becomes small; however, the total energy of the Fe₂CrSi alloy with Fe-Z interchange is extremely high as compared with the other alloys, and hence the possibility that such a state of low spin polarization ratio occurs is extremely low. Consequently, in consideration of the effects of the Z atom, it can be said that Fe₂CrZ inclusive of Fe₂CrGe, namely, Fe₂CrZ (Z=Si., Ge and Sn) is a spintronics material large in spin polarization ratio and insensitive to the atomic disorder.

[Os₂CrZ (Z=Si, Ge and Sn)]

Description is made on the cases where Os homologous to Ru is used as the X atom in the Heusler alloy (X₂YZ).

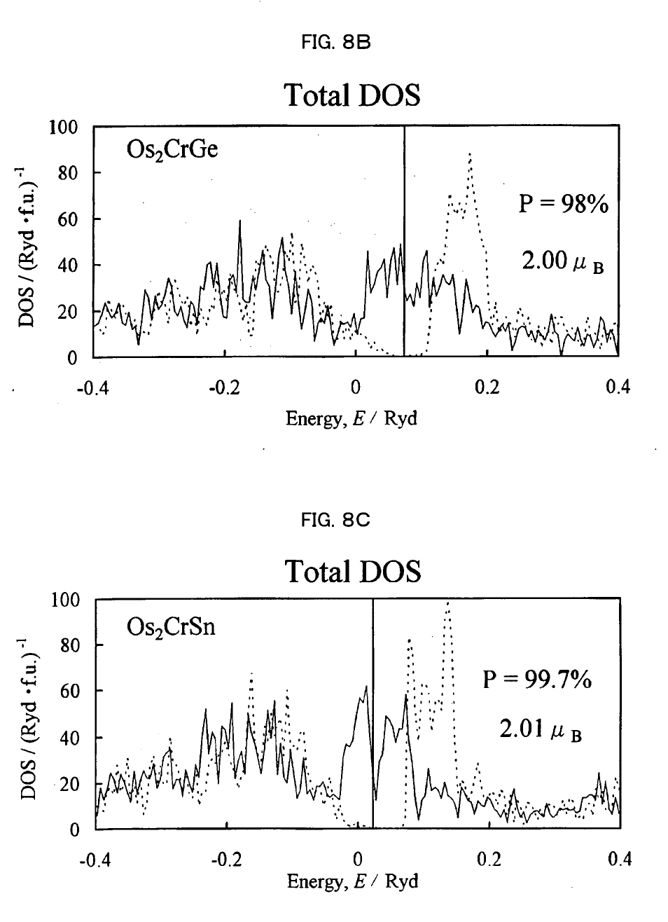

FIG. 8A is a graph showing the densities of state (D(E)) in Os₂CrSi in a ferromagnetic state, FIG. 8B is a graph showing the densities of state (D(E)) in Os₂CrGe in a ferromagnetic state, and FIG. 8C is a graph showing the densities of state (D(E)) in Os₂CrSn in a ferromagnetic state. In each of FIGS. 8A to 8C, the solid and dotted lines represent the up-spin and down-spin densities of state (D(E)), respectively.

As shown in FIG. 8A, it has been possible to predict that Os₂CrSi is a half-metal similarly to Ru₂CrSi. The spin polarization ratios P of Os₂CrSi, Os₂CrGe and Os₂CrSn are as extremely large as 100%, 98% and 99.7%, respectively.

With the X atom varying in the order of Fe, Ru and Os, the peak becomes lower, but the valley for the down-spin becomes wider to facilitate the formation of a half-metal.

[X₂CrP (X=Fe, Ru and Os)]

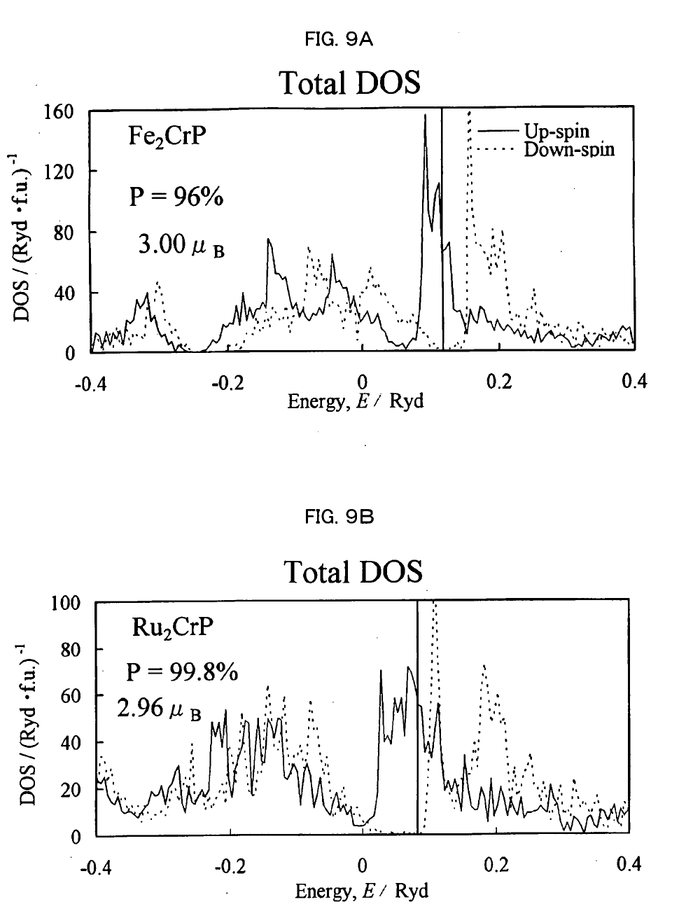

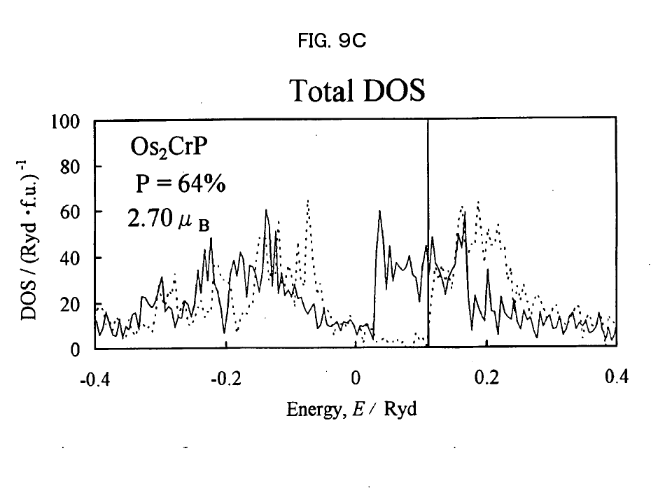

FIG. 9A is a graph showing the densities of state (D(E)) in Fe₂CrP, FIG. 9B is a graph showing the densities of state (D(E)) in Ru₂CrP, and FIG. 9C is a graph showing the densities of state (D(E)) in Os₂CrP. In each of FIGS. 9A to 9C, the solid and dotted lines represent the up-spin and down-spin densities of state (D(E)), respectively.

In the Heusler alloys, the substitution of the Z atoms such as Si, Ge and Sn belonging to the group IVB with P belonging to the group VB does not significantly affect the gross features of the density-of-state curves, merely shifting the position of the Fermi energy E_{F} to the higher energy side. In general, the shape of the density-of-state curves tends to be predominantly affected by the behavior of the d-electrons in the X and Y atoms; thus, the substitution of the Z atom in which the valence electrons are s-electrons and p-electrons with the atoms belonging to the groups IIIB, IVB and VB hardly varies the shape of the density-of-state curves. Accordingly, the substitution of the Z atom can shift the position of the Fermi energy E_{F} without significantly affecting the shape of the density-of-state curves.

The above-mentioned substitution of the X atom in X₂CrZ with Fe, Ru and Os widens the valley in the vicinity of the Fermi energy E_{F}, and tends to yield half-metals; on the other hand, this substitution tends to lower the peak of the density of state, and thereby tends to decrease the D↑(E_{F}) value to reduce the spin polarization ratio P. Accordingly, it can be said that spintronics materials such as new half-metals having high spin polarization ratios will be obtained by intermingling the homologous atoms with each other.

[(FeₓRu₁₋ₓ)₂CrZ (Z=Si, Ge and Sn)]

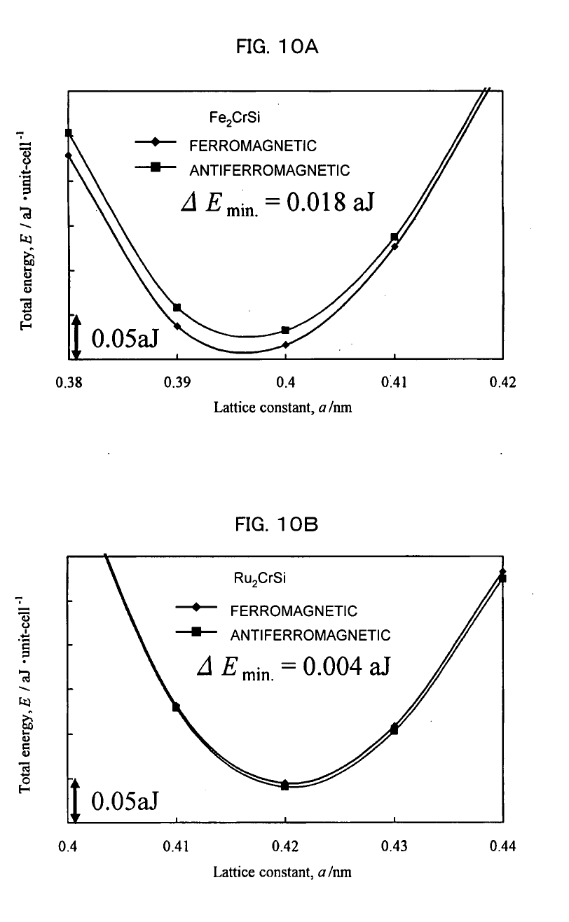

FIG. 10A is a graph showing the relations between the lattice constant and the total energy in the ferromagnetic state and in the antiferromagnetic state in Fe₂CrSi, and FIG. 10B is a graph showing the relations between the lattice constant and the total energy in the ferromagnetic state and in an antiferromagnetic state in Ru₂CrSi.

In Fe₂CrSi, as shown in FIG. 10A, the total energy in the ferromagnetic state is lower than the total energy in the antiferromagnetic state to make the ferromagnetic state more stable. However, as shown in FIG. 5A, Fe₂CrSi is not a half-metal, but is high in spin polarization ratio P to be a spintronics material close to a half-metal.

On the other hand, in Ru₂CrSi, as shown in FIG. 10B, the total energy in the antiferromagnetic state is lower than the total energy in the ferromagnetic state to make the antiferromagnetic state more stable. In other words, although Ru₂CrSi in the ferromagnetic state is a half-metal as shown in FIG. 4A, this state is hardly developed. The present inventors have assumed three types of antiferromagnetic states and a comparison between the total energies has been carried out to find that the same tendency as described above is identified in any of these three types.

Accordingly, the electronic structures in the ferromagnetic and antiferromagnetic states of (FeₓRu₁₋ₓ)₂CrSi with Fe and Ru intermingled as the X atom have been studied.

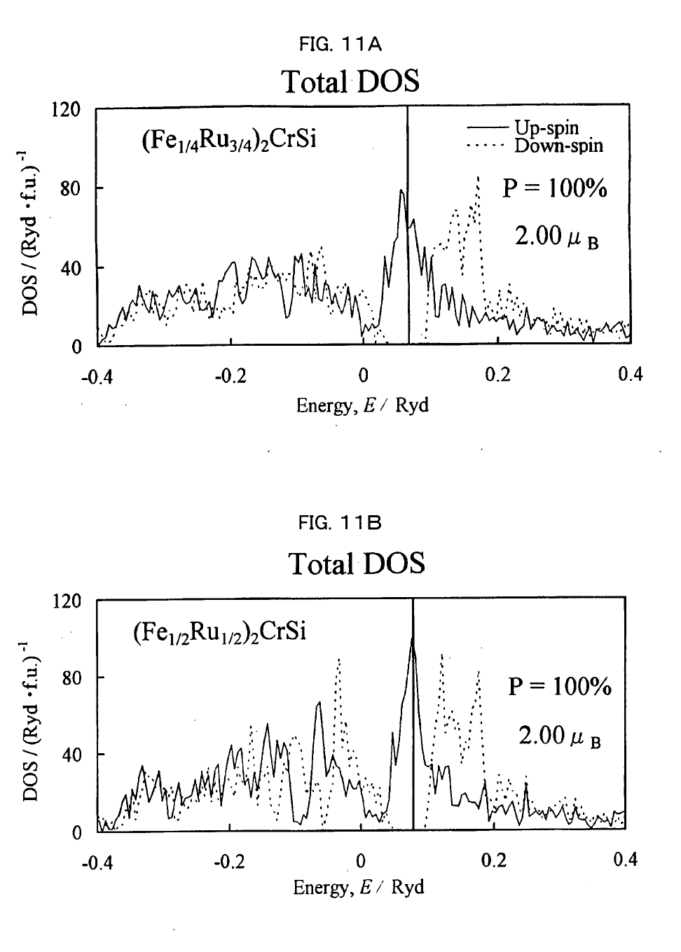

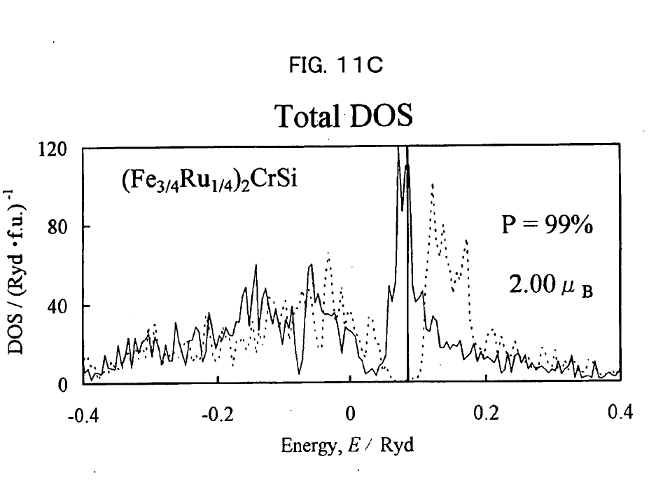

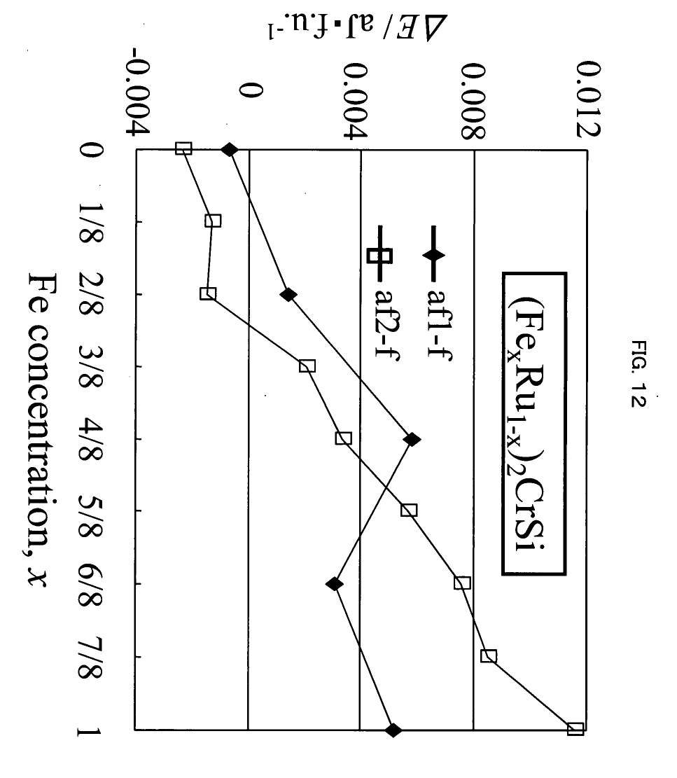

FIG. 11A is a graph showing the densities of state (D(E)) in (Fe_{1/4}Ru_{3/4})₂CrSi, FIG. 11B is a graph showing the densities of state in (Fe_{1/2}Ru_{1/2})₂CrSi, and FIG. 11C is a graph showing the densities of state in (Fe_{3/4}Ru_{1/4})₂CrSi. In each of FIGS. 11A to 11C, the solid and dotted lines represent the up-spin and down-spin densities of state (D(E)), respectively.

As shown in FIGS. 11A to 11C, the spin polarization ratios P of (Fe_{1/4}Ru_{3/4})₂CrSi, (Fe_{1/2}Ru_{1/2})₂CrSi, and (Fe_{3/4}Ru_{1/4})₂CrSi are as extremely high as 100%, 100% and 99%, respectively. In other words, when a ferromagnetic state is obtained with x<¾, such a state leads to a half-metal. Additionally, when a ferromagnetic state is obtained even with x=¾, such a state leads to a spintronics material high in spin polarization ratio P.

FIG. 12 is a graph showing the relations between the total energies difference of the two antiferromagnetic states (af1, af2) from the ferromagnetic state (f) and the Fe concentration (x) in (FeₓRu₁₋ₓ)₂CrSi. In FIG. 12, the energy differences (ΔE) of the antiferromagnetic states from the ferromagnetic state are plotted against x, and the ferromagnetic state can be thereby predicted to be stable in the range of positive ΔE, namely, in the range of ⅓<x.

In (Fe_{3/8}Ru_{5/8})₂CrSi with x=⅜, the ferromagnetic state is low in total energy to be stable; however, in (Fe_{1/4}Ru_{3/4})₂CrSi with x=¼, the antiferromagnetic states are low in total energy to be stable. Accordingly, from a comparison between the total energy of the ferromagnetic state and the total energies of the antiferromagnetic states as a function of x=n/8 (n=1, 2, . . . , 8), (FeₓRu₁₋ₓ)₂CrSi can be predicted to be a half-metal within a range of ⅓≦x≦¾.

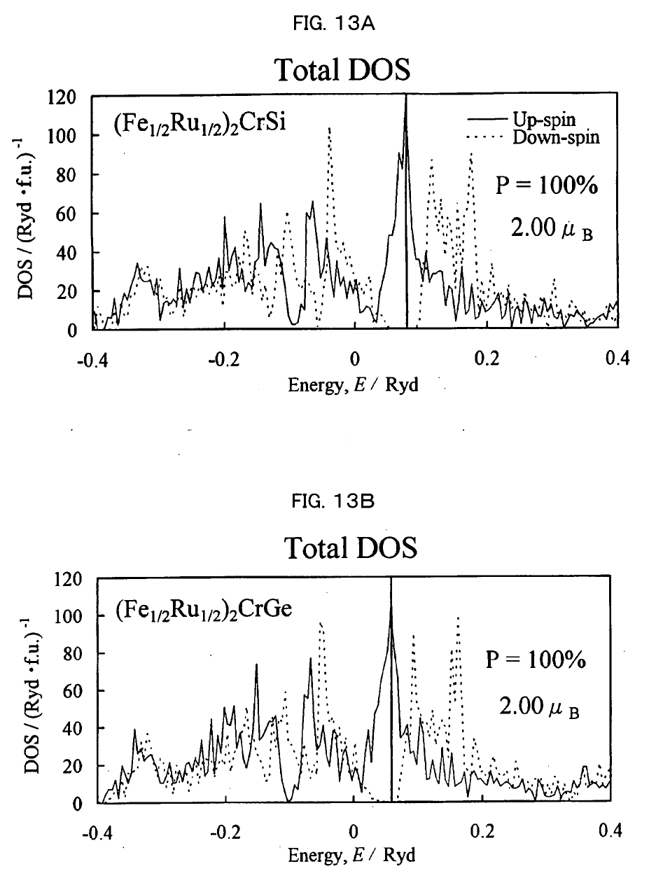

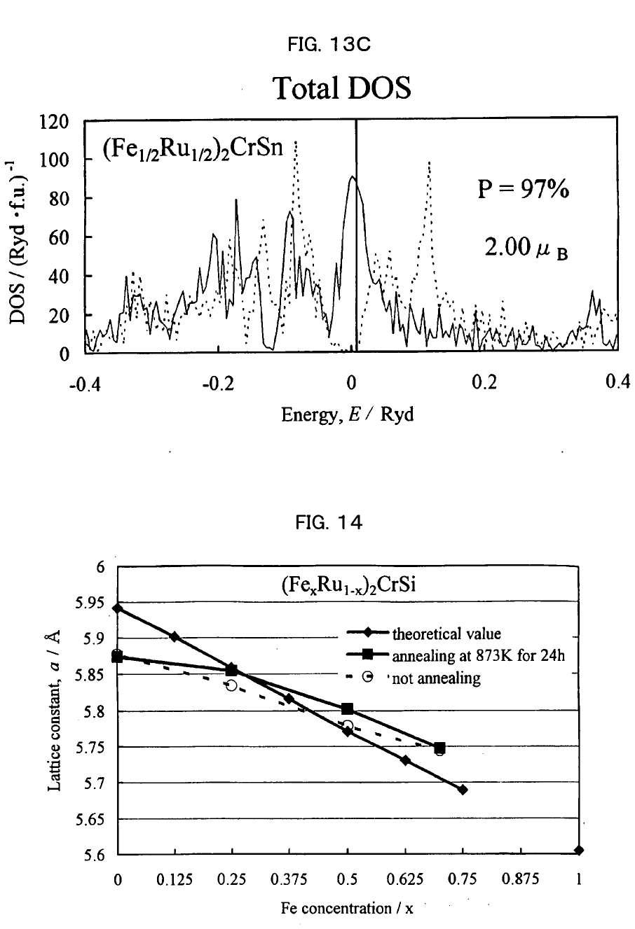

FIG. 13A is a graph showing the densities of state (D(E)) in (Fe_{1/2}Ru_{1/2})₂CrSi, FIG. 13B is a graph showing the densities of state (D(E)) in (Fe_{1/2}Ru_{1/2})₂CrGe, and FIG. 13C is a graph showing the densities of state (D(E)) in (Fe_{1/2}Ru_{1/2})₂CrSn. In other words, the graphs shown in FIGS. 13A to 13C relate to the alloys different in the Z atom from each other. In each of FIGS. 13A to 13C, the solid and dotted lines represent the up-spin and down-spin densities of state (D(E)), respectively.

The spin polarization ratios P of (Fe_{1/2}Ru_{1/2})₂CrSi, (Fe_{1/2}Ru_{1/2})₂CrGe and (Fe_{1/2}Ru_{1/2})₂CrSn are 100%, 100% and 97%, respectively. Consequently, it can be said that (FeₓRu₁₋ₓ)₂CrZ is promising in the range of ⅓<x as a spintronics material high in spin polarization ratio P, and is a promising material particularly in the range of ⅓≦x≦¾ as a half-metal. It is to be noted that Z is any one of the group IIIB elements, the group IVB elements and the group VB elements.

FIG. 14 is a graph showing the relation between the x value and a lattice constant in (FeₓRu₁₋ₓ)₂CrSi. In FIG. 14, the symbol ♦ represents the theoretical values, the symbol ▪ represents the values measured after annealing at 873 K for 24 hours, and the symbol ◯ represents the values measured before annealing. The theoretical values are in agreement with the measured values within an error of approximately 1%, and it can be said that when ⅓<x, (FeₓRu₁₋ₓ)₂CrSi becomes an L2₁-type Heusler alloy in which the ferromagnetic state is stable.

[(XₓX′₁₋ₓ)₂CrSi (X, X′=Fe, Co, Ru, Rh and Os)]

As for the combination of the X atoms, in addition to the homologous-element combinations such as Fe_{1/2}Os_{1/2} and Ru_{1/2}Os_{1/2}, also effective are the combinations such as Fe_{1/2}Co_{1/2} and Ru_{1/2}Rh_{1/2}, in which Co and Rh, respectively larger by one in atomic number than Fe. and Ru, are incorporated.

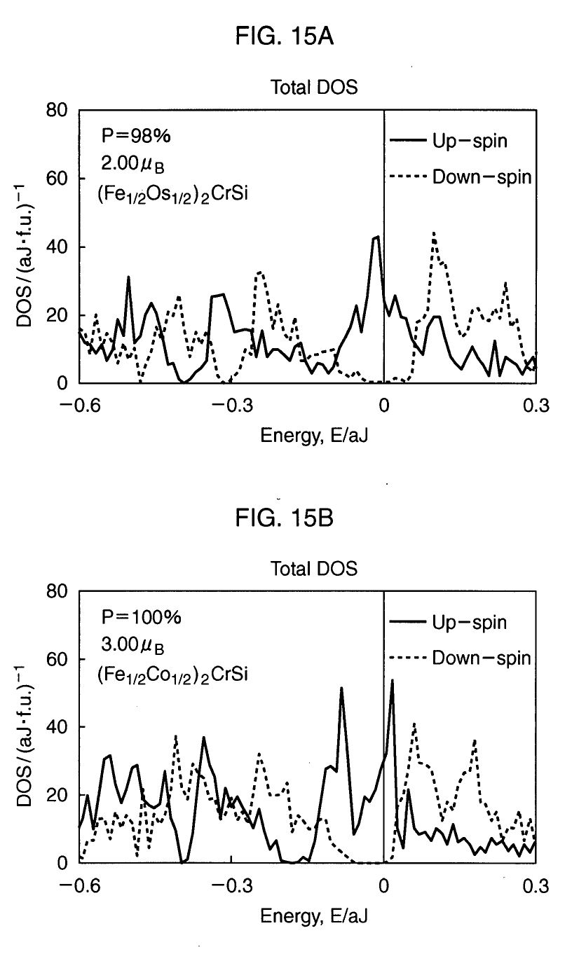

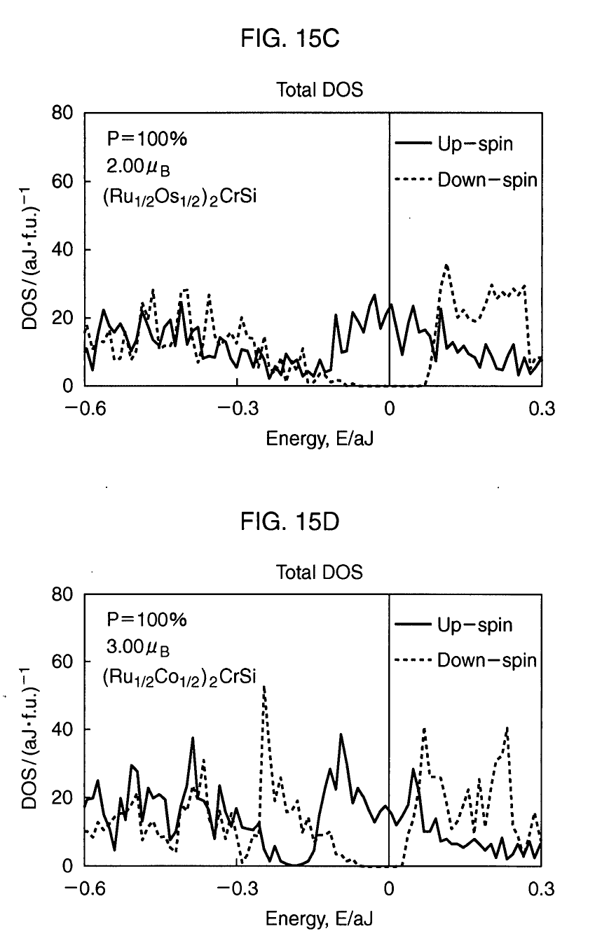

FIG. 15A is a graph showing the densities of state (D(E)) in (Fe_{1/2}Os_{1/2})₂CrSi, FIG. 15B is a graph showing the densities of state (D(E)) in (Fe_{1/2}Co_{1/2})₂CrSi, FIG. 15C is a graph showing the densities of state (D(E)) in (Ru_{1/2}Os_{1/2})₂CrSi, and FIG. 15D is a graph showing the densities of state (D(E)) in (Ru_{1/2}Co_{1/2})₂CrSi. In each of FIGS. 15A to 15D, the solid and dotted lines represent the up-spin and down-spin densities of state (D(E)), respectively.

As shown in FIGS. 15A to 15D, in each of the cases where Fe, Ru and/or Os is included in the combination of the X atoms, the up-spin density of state at the Fermi energy is high and the spin polarization ratio P is high.

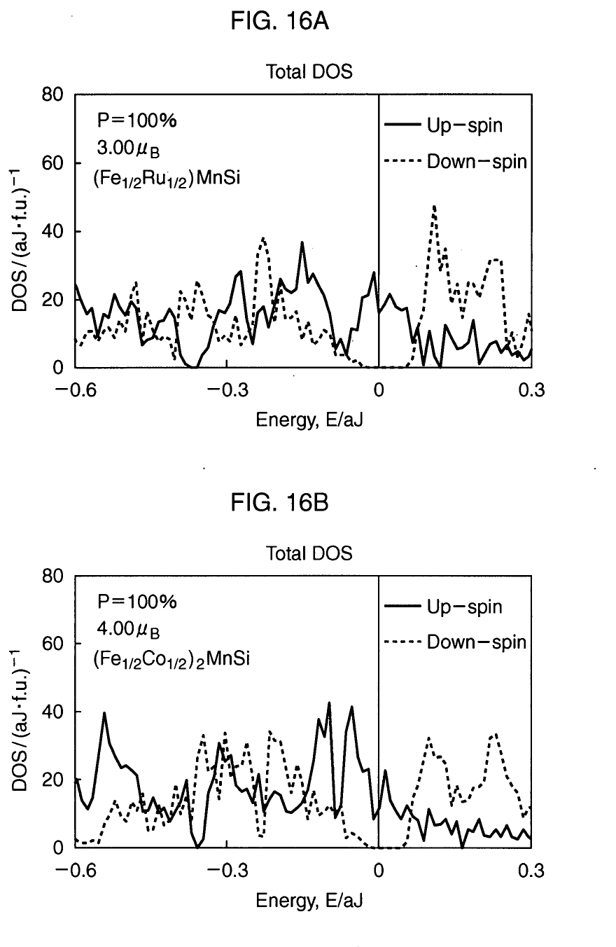

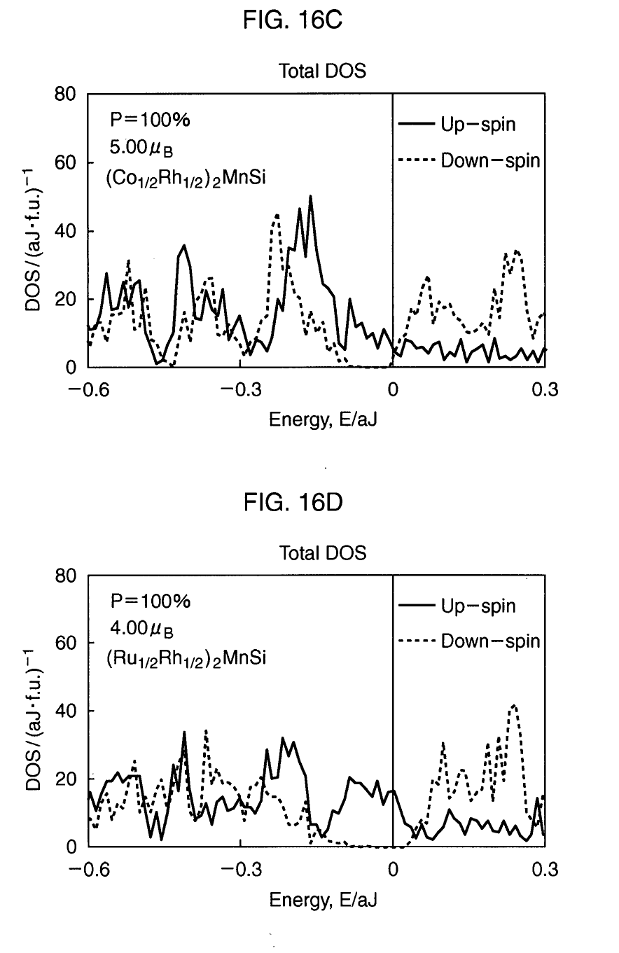

FIG. 16A is a graph showing the densities of state (D(E)) in (Fe_{1/2}Ru_{1/2})₂MnSi, FIG. 16B is a graph showing the densities of state (D(E)) in (Fe_{1/2}Co_{1/2})₂MnSi, FIG. 16C is a graph showing the densities of state (D(E)) in (Co_{1/2}Rh_{1/2})₂MnSi, and FIG. 16D is a graph showing the densities of state (D(E)) in (Ru_{1/2}Rh_{1/2})₂MnSi. In each of FIGS. 16A to 16D, the solid and dotted lines represent the up-spin and down-spin densities of state (D(E)), respectively.

As shown in FIGS. 16A to 16D, in each of the cases where Fe, Ru and/or Os is included in the combination of the X atoms, the up-spin density of state at the Fermi energy is high and the spin polarization ratio P is high. On the contrary, in the cases where the X atom includes Co and Rh, the spin polarization P is high, but the peak of the down-spin density of state has its tail exactly at the Fermi energy, leading to a prediction that the decrease of the spin polarization ratio P is caused by the disorder in the atomic arrangement and other causes.

[X₂(Mn_{1-y}Cr_{y})Si (X=Fe and Ru)]

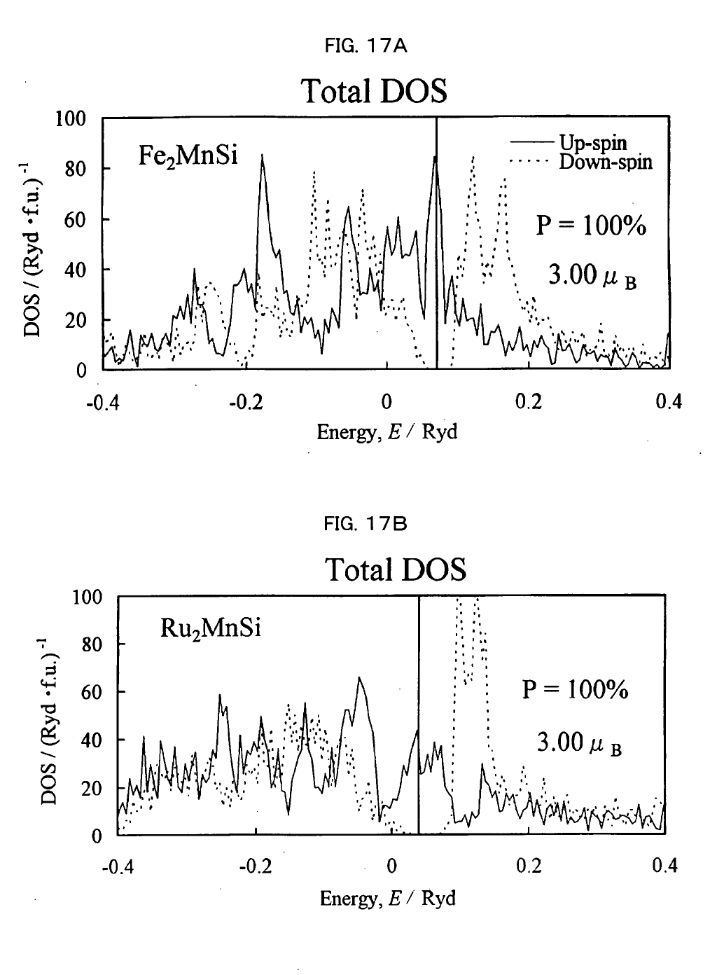

Next, description is made with a focus on the Y atom in the Heusler alloy. FIG. 17A is a graph showing the densities of state (D(E)) in a ferromagnetic state in Fe₂MnSi, and FIG. 17B is a graph showing the densities of state (D(E)) in a ferromagnetic state in Ru₂MnSi. In each of FIGS. 17A and 17B, the solid and dotted lines represent the up-spin and down-spin densities of state (D(E)), respectively.

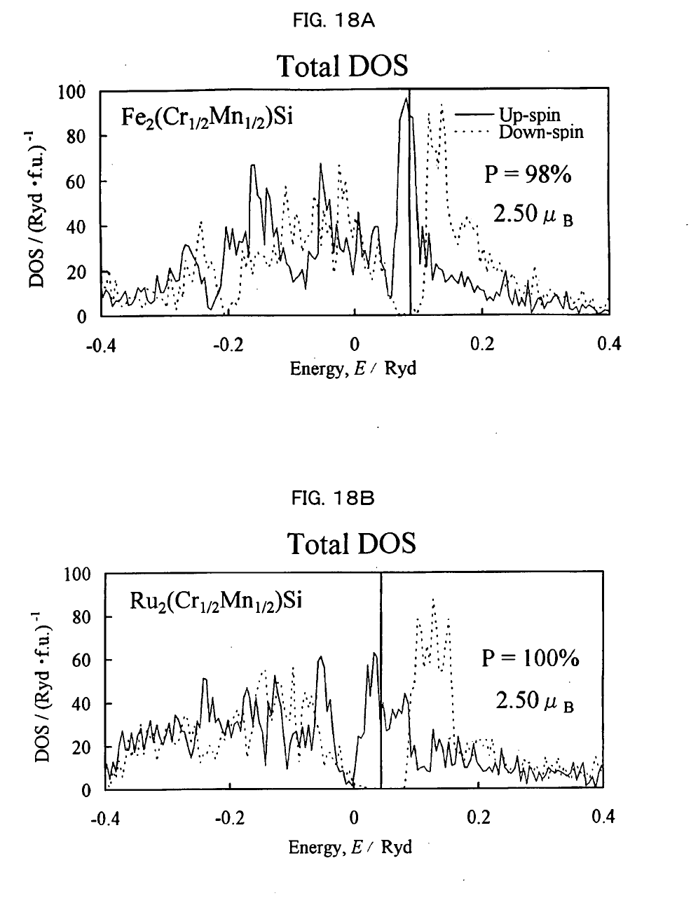

These alloys each include an antiferromagnetic component in the magnetic moment, and cannot be expected to be a half-metal, but become a half-metal in the ferromagnetic state. In view of the fact that Fe₂CrSi is stable in the ferromagnetic state, Fe₂ (Mn_{1-y}Cr_{y})Si becomes a half-metal with a high possibility. FIG. 18A is a graph showing the densities of state (D(E)) in a ferromagnetic state in Fe₂(Cr_{1/2}Mn_{1/2})Si, and FIG. 18B is a graph showing the densities of state (D(E)) in a ferromagnetic state in Ru₂(Cr_{1/2}Mn_{1/2})Si. In each of FIGS. 18A and 18B, the solid and dotted lines represent the up-spin and down-spin densities of state (D(E)), respectively.

As shown in FIGS. 18A and 18B, Ru₂(Cr_{1/2}Mn_{1/2})Si is a half-metal, and Fe₂(Cr_{1/2}Mn_{1/2})Si is not a half-metal, but has a spin polarization ratio P as high as 98%. In other words, the features of these alloys are similar to those of the X₂CrZ alloys. Particularly, there are found a high up-spin peak and a large down-spin valley in the vicinity of the Fermi energy E_{F}, both to be significant in the identification of a spintronics material. Consequently, these alloys can also be said to be spintronics materials high in spin polarization ratio provided that the ferromagnetic states are stable.

Here, it should be noted that in a reference paper “J. Phys. Soc. Jpn., Vol. 64, No. 11, November, 1995, pp. 4411-4417,” the magnetic moment of Fe₂Mn_{1/2}Cr_{1/2}Si was measured to be 2.5 as shown FIG. 10 of the paper. This result is in agreement with the result shown in FIG. 18A, indicating that the reliability of the prediction made by the present inventors is high.

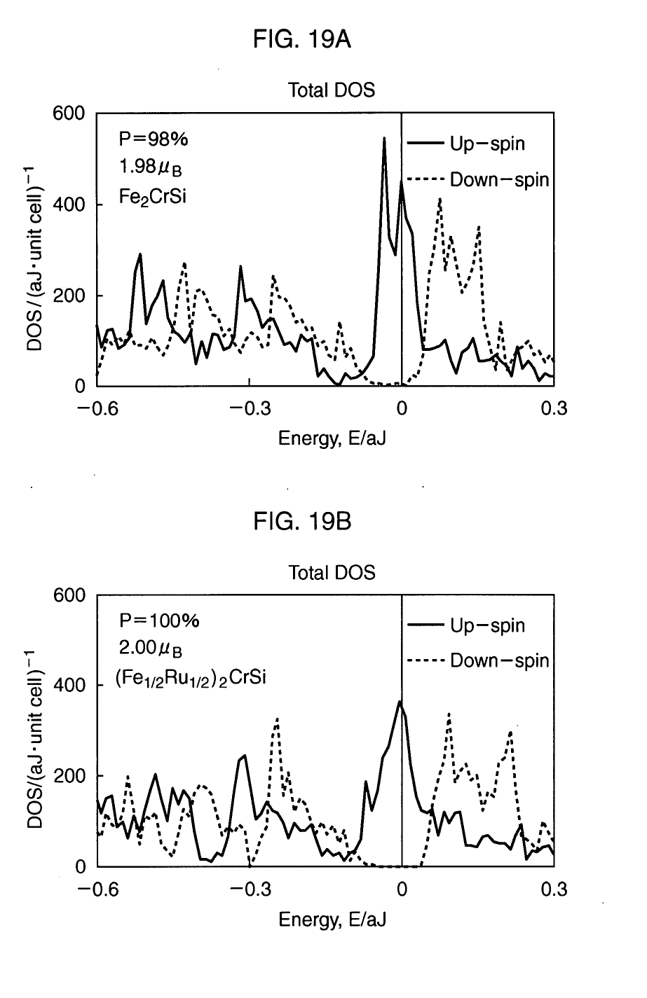

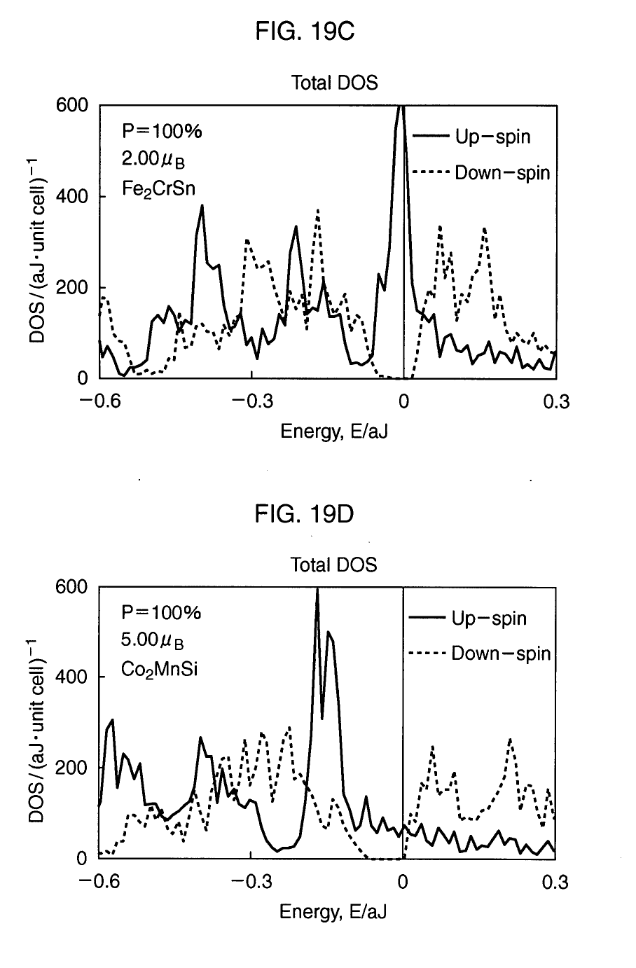

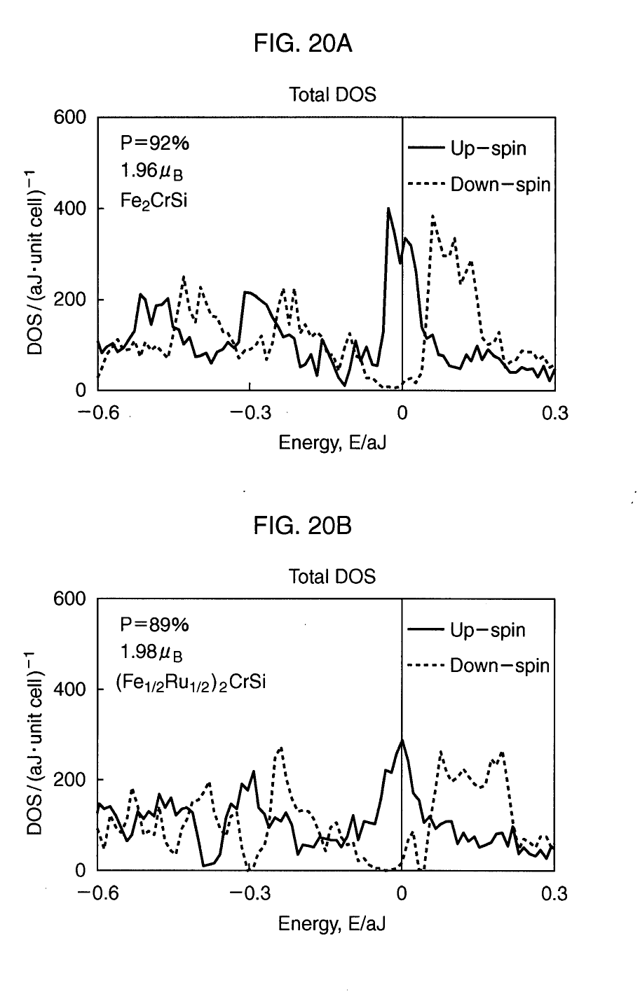

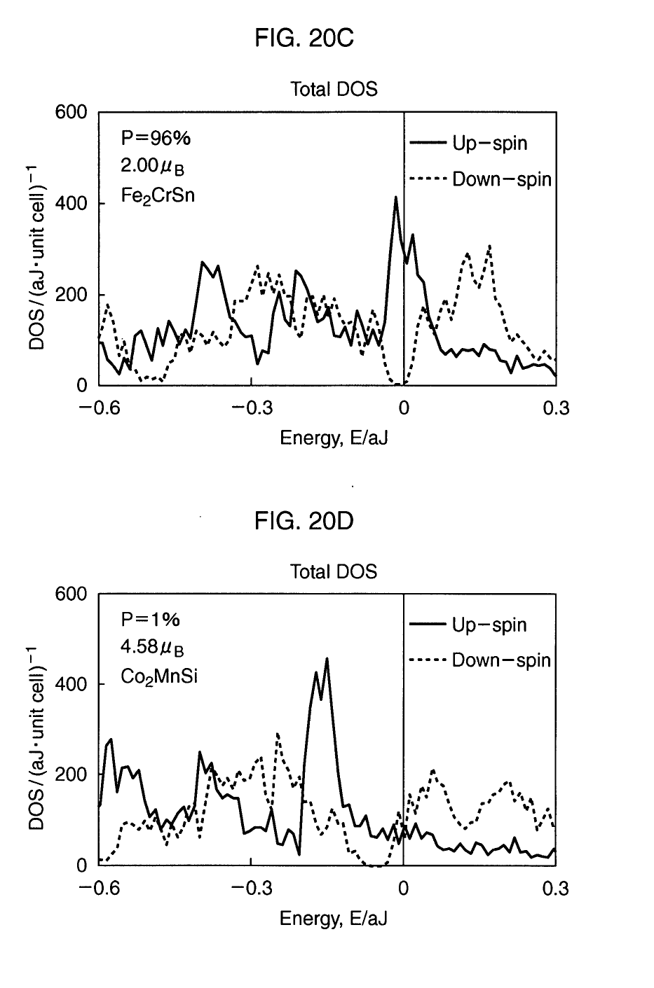

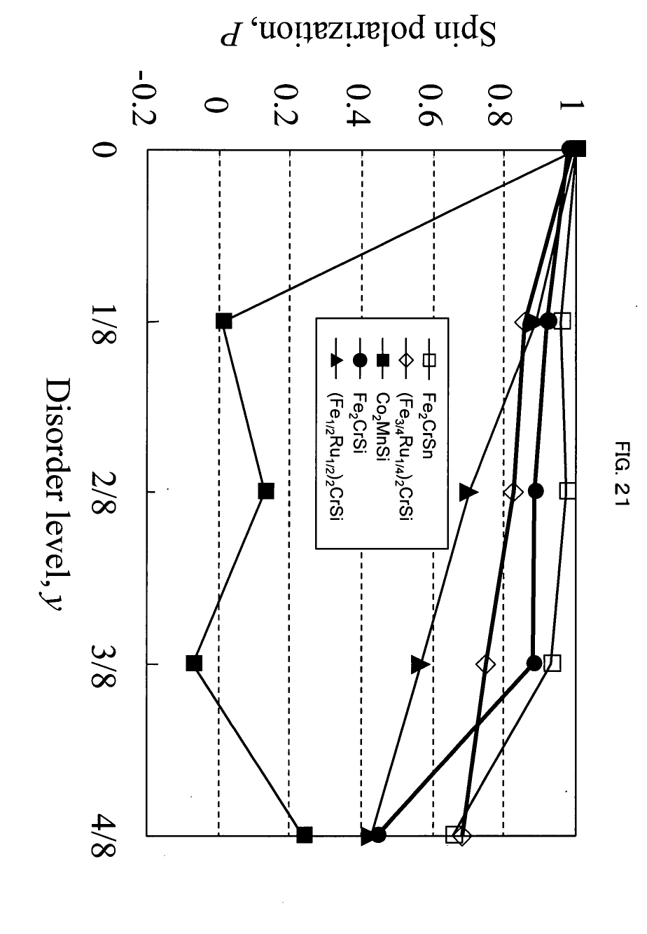

FIG. 19A is a graph showing the densities of state (D(E)) in Fe₂CrSi in which atoms are regularly arranged, FIG. 19B is a graph showing the densities of state (D(E)) in (Fe_{1/2}Ru_{1/2})₂CrSi in which atoms are regularly arranged, FIG. 19C is a graph showing the densities of state (D(E)) in Fe₂CrSn in which atoms are regularly arranged, and FIG. 19D is a graph showing the densities of state (D(E)) in Co₂MnSi in which atoms are regularly arranged. Additionally, FIG. 20A is a graph showing the densities of state (D(E)) in Fe₂CrSi in which atoms are irregularly arranged, FIG. 20B is a graph showing the densities of state (D(E)) in (Fe_{1/2}Ru_{1/2})₂CrSi in which atoms are irregularly arranged, FIG. 20C is a graph showing the densities of state (D(E)) in Fe₂CrSn in which atoms are irregularly arranged, and FIG. 20D is a graph showing the densities of state (D(E)) in Co₂MnSi in which atoms are irregularly arranged. In each of FIGS. 19A to 19D and FIGS. 20A to 20D, the solid and dotted lines represent the up-spin and down-spin densities of state (D(E)), respectively. It is to be noted that the atomic disorder level is ⅛ in FIGS. 20A to 20D.

As shown in FIGS. 19A to 19D and FIGS. 20A to 20D, in the three Fe-containing alloys (FIGS. 19A to 19C and FIGS. 20A to 20C), the atomic disorder between Fe and Cr is stable in energy, and high spin polarization ratios P are thereby obtained even in the irregular arrangements. On the contrary, in the Co₂MnSi undergoing atomic disorder between Co and Mn, the spin polarization ratio P is drastically decreased. Such a tendency may conceivably found in (CO_{1/2}Rh_{1/2})₂MnSi shown in FIG. 16C.

FIG. 21 is a graph showing the relations between the disorder level y of Cr or Mn and the spin polarization ratio P in five alloys. In each of the irregular arrangements in Fe₂CrSn, (Fe_{3/4}Ru_{1/4})₂CrSi, Fe₂CrSi and (Fe_{1/2}Ru_{1/2})₂CrSi, an atomic disorder is assumed to occur between Fe and Cr. In the irregular arrangement in Co₂MnSi, an atomic disorder is assumed to occur between Co and Mn. The irregular arrangements in these alloys are stable in energy.

As shown in FIG. 21, in each of the four Fe-containing alloys, the spin polarization ratio P is decreased moderately even with the increase of the disorder level y, but in Co₂MnSi, the spin polarization ratio P is drastically decreased even with the disorder level y only reaching ⅛.

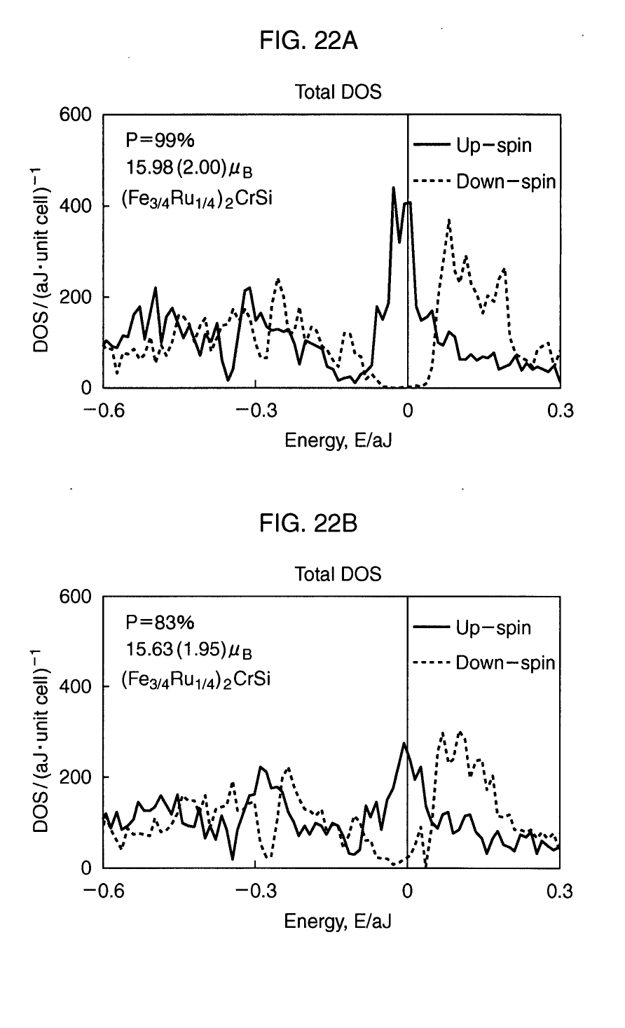

FIG. 22A is a graph showing the densities of state (D(E)) in (Fe_{3/4}Ru_{1/4})₂CrSi in which atoms are regularly arranged, and FIG. 22B is a graph showing the densities of state (D(E)) in (Fe_{3/4}Ru_{1/4})₂CrSi in which atoms are irregularly arranged. It is to be noted that the atomic disorder level in FIG. 22B is ¼ and this composition is associated with the most stable energy.

As shown in FIGS. 22A and 22B, in either of the regular and irregular arrangements, the density of state for the up-spin state at the Fermi energy E_{F} D↑(E_{F}) is high; however, the D↓(E_{F}) value in the irregular arrangement is somewhat lower than that in the regular arrangement.

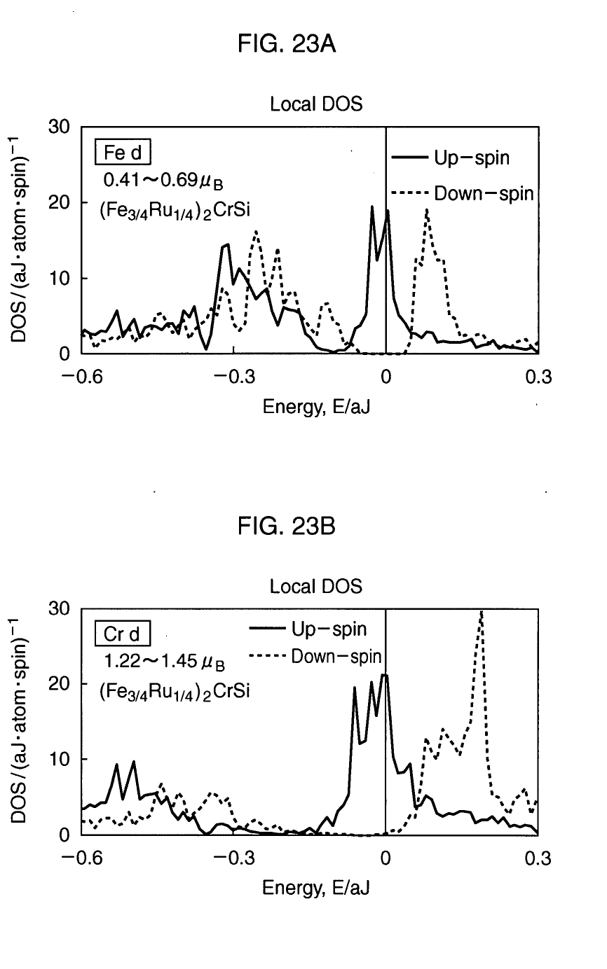

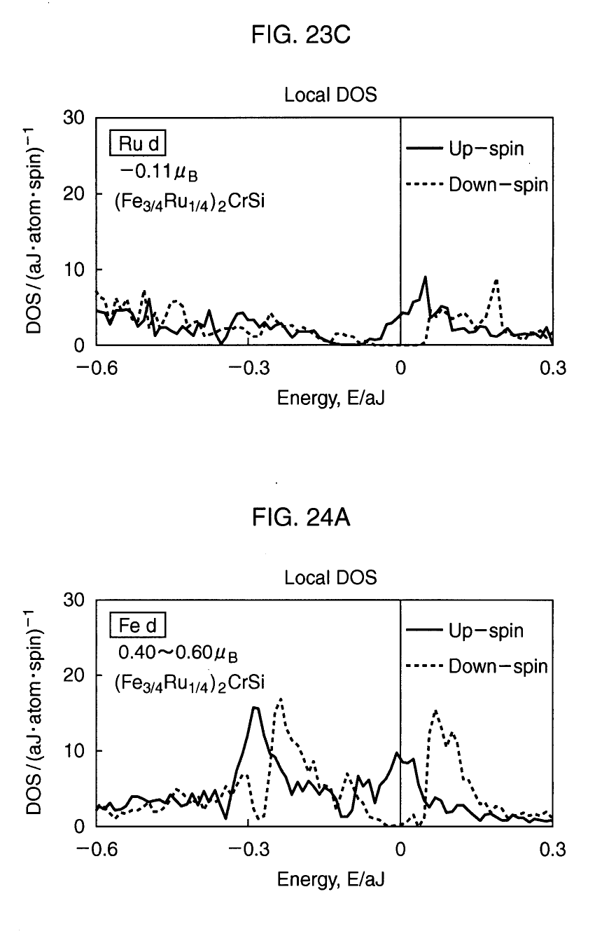

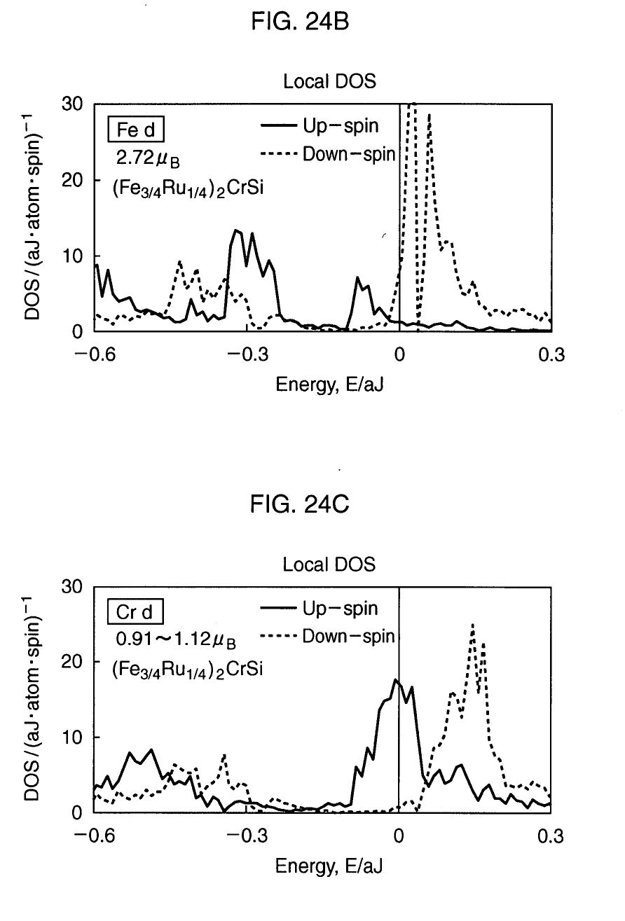

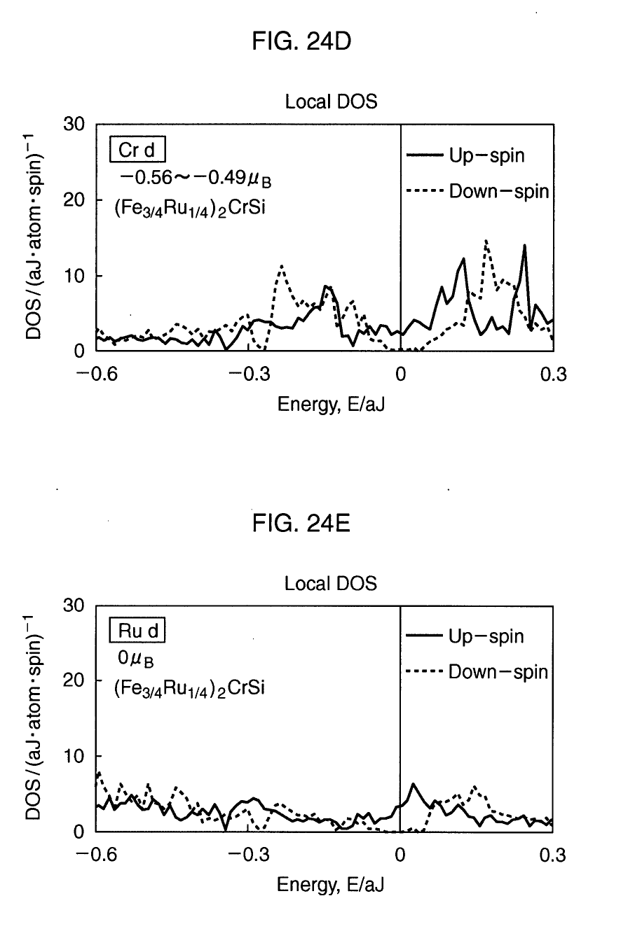

FIG. 23A is a graph showing the densities of state (D(E)) of the Fe d-component in (Fe_{3/4}Ru_{1/4})₂CrSi in which atoms are regularly arranged, FIG. 23B is a graph showing the densities of state (D(E)) of the Cr d-component in (Fe_{3/4}Ru_{1/4})₂CrSi in which atoms are regularly arranged, and FIG. 23C is a graph showing the densities of state (D(E)) of the Ru d-component in (Fe_{3/4}Ru_{1/4})₂CrSi in which atoms are regularly arranged. Additionally, FIG. 24A is a graph showing the densities of state (D(E)) of the d-component of the Fe located at normal positions in (Fe_{3/4}Ru_{1/4})₂CrSi in which atoms are irregularly arranged, FIG. 24B is a graph showing the densities of state (D(E)) of the d-component of the Fe occupying atomic positions other than the normal positions in (Fe_{3/4}Ru_{1/4})₂CrSi in which atoms are irregularly arranged, FIG. 24C is a graph showing the densities of state (D(E)) of the d-component of the Cr located at normal positions in (Fe_{3/4}Ru_{1/4})₂CrSi in which atoms are irregularly arranged, FIG. 24D is a graph showing the densities of state (D(E)) of the d-component of the Cr occupying atomic positions other than the normal positions in (Fe_{3/4}Ru_{1/4})₂CrSi in which atoms are irregularly arranged, and FIG. 24E is a graph showing the densities of state (D(E)) of the d-component of the Ru located at normal positions in (Fe_{3/4}Ru_{1/4})₂CrSi in which atoms are irregularly arranged. As described above, FIGS. 24A, 24C and 24E each show the local density of state associated with the atoms located at the normal positions, and FIGS. 24B and 24D each show the local density of state associated with the atoms occupying the atomic positions other than the normal positions.

As shown in FIGS. 23A to 23C, in the regular arrangements, the local densities of state of Fe and Cr are extremely high. As shown in FIGS. 24A to 24E, in the irregular arrangements, the local densities of the Fe and Cr occupying the atomic positions other than the normal positions are low, but the local densities of state of the Fe and Cr located at the normal positions remain high.

From the results of the analysis on (FeₓRu₁₋ₓ)₂CrSi, the following features are drawn.

(A) (FeₓRu₁₋ₓ)₂CrSi is a material ferromagnetic and high in spin polarization ratio when x is. larger than ⅓.

(B) The reason for the high spin polarization ratio is the fact that the density of state for the up-spin state is large and the density of state for the down-spin state is small.

(C) The reason for the large density of state for the up-spin state is the fact that the local densities of state of Fe and Cr are large. The contribution from Ru is also found although it is not so large as the contributions from Fe and Cr.

As described above in detail, from the results on several alloys, the following features may be derived.

(1) In searching for materials, high in spin polarization ratio such as half-metals, among the Heusler alloys X₂YZ (L2₁ type), the up-spin density of state is provided with a peak in the vicinity of the Fermi level and the down-spin density of state is provided with a deep valley in the vicinity of the Fermi level, by selecting as the X atom one element from “Fe, Ru, Os, Co and Rh” or by combining two or more of these elements in an appropriate ratio, and by selecting as the Y atom one element from “Cr and Mn” or by combining both in an appropriate ratio.

(2) Variation of the X atom successively in the order of a 3d transition element (Fe or Co), a 4d transition element (Ru or Rh) and a 5d transition element (Os or Ir) lowers the peak in the up-spin density of state, but widens the valley in the down-spin density of state, so as to comprehensively facilitate the preparation of a half-metal.

(3) In view of the fact that the homologous elements (the elements lying in the same column in the periodic table) are similar to each other in properties and the Z atom does not significantly affect the electronic structure (the E(k) curves and the density-of-state curves), X₂(Mn_{1-y}Cr_{y}) Z (wherein X is at least one element selected from the group consisting of Fe, Ru, Os, Co and Rh, and Z is at least one element selected from the group consisting of the group IIIB elements, the group IVB elements and the group VB elements) can be said to be a material high in spin polarization ratio such as half-metals to be hardly break down in relation to the disorder in the atomic arrangement.

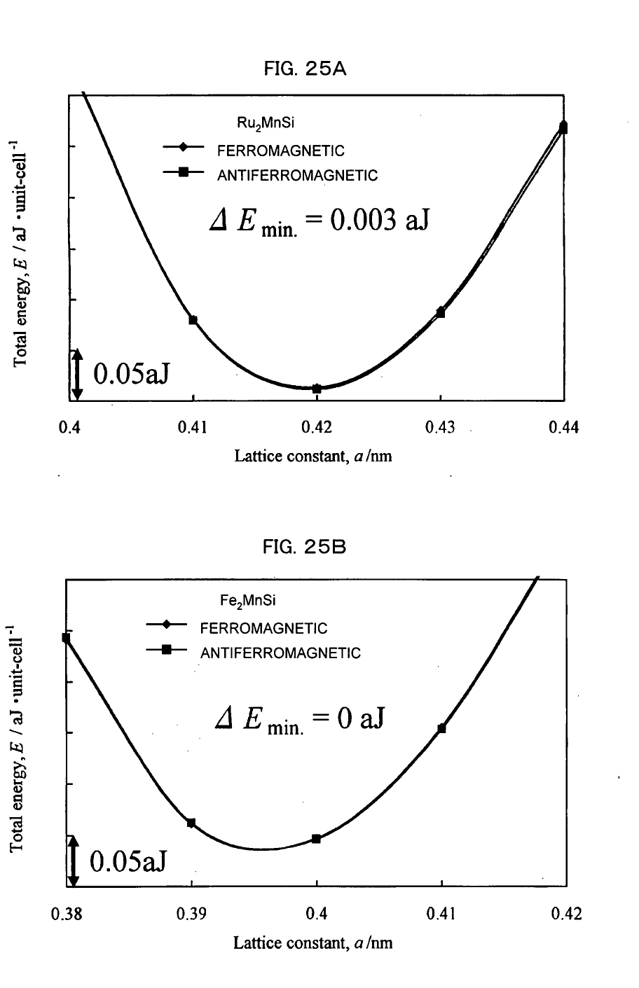

However, Fe₂MnZ and Ru₂MnZ are not provided with stable ferromagnetic states, and are hardly said to be appropriate as spintronics materials. FIG. 25A is a graph showing the relations between the lattice constant and the total energy in the ferromagnetic state and in the antiferromagnetic state in Ru₂MnSi, and FIG. 25B is a graph showing the relations between the lattice constant and the total energy in the ferromagnetic state and in the antiferromagnetic state in Fe₂MnSi.

As shown in FIG. 25A, in Ru₂MnZ, the antiferromagnetic state is stabilized. Also as shown in FIG. 25B, in Fe₂MnZ, the ferromagnetic state and the antiferromagnetic state compete against each other. In this way, in any of Fe₂MnZ and Ru₂MnZ, no stable ferromagnetic state is obtained.

Additionally, in Co₂MnZ, the majority-spin (↑) DOS value at the Fermi energy E_{F} is small, and the spin polarization ratio P tends to be decreased due to the atomic disorder and other causes.

Further, in Co₂CrAl, as is known, the two-phase separation occurs and no half-metal is formed.

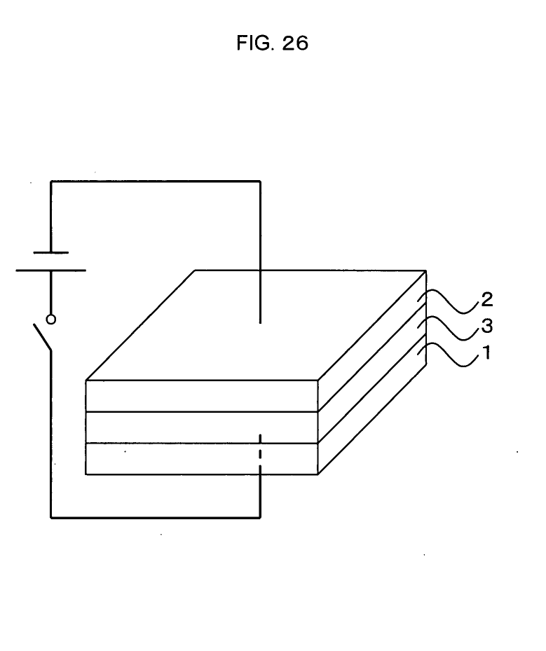

Further, the above described spintronics materials are suitable for TMR devices. For example, as shown in FIG. 26, a TMR device can be formed by sandwiching a nonmagnetic layer 3 between ferromagnetic layers 1 and 2 each formed of a spintronics material.

Incidentally, the following relation is found between the spin polarization ratio P and the TMR value to be used in the report of experimental results. As described above, the spin polarization ratio P is given by
(D↑(E_{F})−D↓(E_{F}))/(D↑(E_{F})+D↓(E_{F})
where D↑(E_{F}) represents the density of state for the up-spin state at the Fermi energy E_{F} and D↓(E_{F}) represents the density of state for the down-spin state at the Fermi energy E_{F}. On the other hand, the TMR value is given by 2P₁P₂/(1−P₁P₂) where P₁ and P₂ represent the spin polarization ratios of the ferromagnetic layers 1 and 2, respectively.

Further, when the ferromagnetic layers 1 and 2 are both half-metals (P₁=P₂=1), the TMR value becomes infinity. Additionally, when the spin polarization ratios of the ferromagnetic layers 1 and 2 share an identical value P₀, the TMR value is given by 2P₀²/(1−P₀²).

The TMR value of Co₂Cr_{0.6}Fe_{0.4}Al has hitherto been reported to be 0.265 (26.5%) at a temperature of 5 K (Jpn. J. Appl. Phys., Vol. 42 (2003), pp. L419 to L422). The spin polarization ratio P₀ corresponding to the TMR value of 0.265 is 0.342 (34.2%). In the above described various materials (inclusive of half-metals) verified by the present inventors, the spin polarization ratios of 60% or more are obtained, and thus, it can be said that according to the present invention, remarkably high spin polarization ratios are obtained as compared to Co₂Cr_{0.6}Fe_{0.4}Al. Incidentally, the TMR value corresponding to the spin polarization ratio of 60% is 1.059 (105.9%), manifesting a large difference between the spin polarization ratio value and the TMR value, so that the spin polarization ratio of 60% can be evaluated to be a high spin polarization ratio.

### INDUSTRIAL APPLICABILITY

As described above in detail, according to the present invention, a sufficiently high spin polarization ratio can be obtained. A material having a spin polarization of 100% can be used as a half-metal.

1: A spintronics material containing X₂(Mn_{1-y}Cr_{y})Z wherein:
X is a combination of two or more elements including one element selected from a group consisting of Fe, Ru, Os, Co and Rh, and including at least one element selected from transition elements exclusive of said one element;
Z is at least one element selected from a group consisting of the group IIIB elements, the group IVB elements and the group VB elements; and
y is 0 or more and 1 or less.

2: The spintronics material according to claim 1, wherein a spin polarization ratio is substantially 60% or more.

3: A TMR device comprising:
two ferromagnetic layers composed of the spintronics material according to claim 1; and
a nonmagnetic layer sandwiched between the two ferromagnetic layers.

4: The TMR device according to claim 3, wherein a spin polarization ratio of the spintronics material is substantially 60% or more.
